(19) United States
(12) Patent Application Publication
(10) Pub. No.: US 2024/0322084 A1
(43) Pub. Date: Sep. 26, 2024

(54) SEMICONDUCTOR LIGHT-EMITTING ELEMENT, AND DISPLAY DEVICE

(71) Applicant: LG ELECTRONICS INC., Seoul (KR)

(72) Inventors: Jinsung KIM, Seoul (KR); Wonjae CHANG, Seoul (KR); Wonseok CHOI, Seoul (KR)

(73) Assignee: LG ELECTRONICS INC., Seoul (KR)

(21) Appl. No.: 18/573,895

(22) PCT Filed: Jul. 5, 2021
(86) PCT No.: PCT/KR2021/008491

§ 371 Date: Dec. 22, 2023

(51) Int. Cl. H01L 33/44; H01L 25/16

(52) U.S. Cl. CPC H01L 33/44; H01L 25/167

(57) ABSTRACT

A semiconductor light emitting device includes a light emitting structure having a first region and a second region along a major axis direction, an insulating layer surrounding a side surface of the first region, and a first electrode surrounding a side surface of the second region. The thickness of the insulating layer is the same as the thickness of the first electrode. Therefore, when implementing a display, lighting defects can be prevented and luminance deviation can be eliminated, thereby improving image quality.

### TECHNICAL FIELD

The embodiment relates to a semiconductor light emitting device and a display device.

### BACKGROUND ART

A display device displays high-definition image using self-emissive element such as a light emitting diode as a light source for a pixel. The light emitting diode exhibits excellent durability even under harsh environmental conditions and is capable of long lifespan and high luminance, so that that it is attracting attention as a light source for next-generation display devices.

Recently, research is in progress to manufacture ultra-small light emitting diodes using highly a material having reliable inorganic crystal structure and dispose them on the panel of a display device (hereinafter referred to as “display panel”) to use them as a light source for a next-generation pixel.

This display device is expanding beyond a flat display into various forms such as a flexible display, a foldable display, a stretchable display, and a rollable display.

In order to realize high resolution, the size of the pixel is gradually becoming smaller, and numerous light emitting devices must be aligned in the smaller pixel, so that research on the manufacture of ultra-small light emitting diodes as small as micro- or nano-scale is actively taking place.

Due to improvements in the manufacturing process, not only micro-scale light emitting diode but also nano-scale light emitting diode are manufactured, and thus it is possible to implement an ultra-high resolution display using these light emitting diodes.

The nano-scale light emitting diode as well as the micro-scale light emitting diode are usually manufactured through a growth process and an etching process.

For example, after a semiconductor layer is grown on a wafer, the semiconductor layer is etched using a dry etching process to manufacture a light emitting diode.

Plasma is formed for the dry etching process, and the density of this plasma varies depending on the location of the wafer. When an etching process is performed using plasma with different densities depending on the location of the wafer, the degree of etching of the semiconductor layer can vary depending on the location of the wafer, and the diameter or length of the manufactured light emitting diode can be different.

In addition, in order to manufacture nano-scale light emitting diodes, nano-scale patterns must be formed, but there is a problem in forming such nano-scale patterns. In addition, when the formed nano-scale patterns have different sizes, the diameters of light emitting diodes manufactured using the nano-scale patterns as masks can be different.

Different diameters mean different light emitting areas. Therefore, when a display is implemented using different light emitting diodes, the luminance of each pixel is different from each other, resulting in poor image quality.

FIG. 1 shows light emitting diodes mounted on a substrate to implement a display in the related art.

When the manufactured light emitting diodes have different lengths, as shown in FIG. 1, at least one of both ends of the light emitting diode does not contact the wiring electrodes 5 and 6, resulting in lighting defects. As shown in FIG. 1, the light emitting diode 1 having a normal length is disposed on an electrode and lights up, whereas the light emitting diode 3 having a short length does not light up because it is not in contact with at least one electrode.

Therefore, when manufacturing nano-scale light emitting diodes using an etching process as in the prior art, since the diameter and length of the manufactured nano-scale light emitting diodes 3 are different, the number of pixels that do not light up when implementing a display is too large, making mass production impossible.

Meanwhile, in the related art, since the semiconductor layer is etched using dry etching, there is a problem that the roughness of the etched surface of the semiconductor layer is not good.

### DISCLOSURE

### Technical Problem

An object of the embodiment is to solve the foregoing and other problems.

Another object of the embodiment is to provide a semiconductor light emitting device having the same diameter and/or length (or height).

Another object of the embodiment is to provide a semiconductor light emitting device that does not require forming a separate electrode after manufacturing the semiconductor light emitting device.

Another object of the embodiment is to provide a semiconductor light emitting device that does not require forming a separate insulating layer after manufacturing the semiconductor light emitting device.

Additionally, the embodiment provides a semiconductor light emitting device that can be freely manufactured into a desired shape.

Another object of the embodiment is to provide a display device that can minimize lighting defects.

Additionally, another object of the embodiment is to provide a display device that can ensure lighting uniformity of each pixel.

The technical problems of the embodiment are not limited to those described in this item, and comprise those that can be understood through the description of the invention.

### Technical Solution

In order to achieve the above or other objects, according to a first aspect of the embodiment, a semiconductor light emitting device, comprising: a light emitting structure having a first region and a second region along the major axis direction; an insulating layer surrounding a side surface of the first region; and a first electrode surrounding a side surface of the second region, wherein the thickness of the insulating layer is the same as the thickness of the first electrode.

According to a second aspect of the embodiment to achieve the above or other objects, a display device, comprising: a substrate; first and second assembling wirings on the substrate; a plurality of semiconductor light emitting devices disposed on the first and second assembling wirings to generate different color lights; a first wiring electrode on one side of each of the plurality of semiconductor light emitting devices; and a second wiring electrode on the other side of each of the plurality of semiconductor light emitting devices.

### Advantageous Effects

The effects of the semiconductor light emitting device and the display device according to the embodiment are described as follows.

According to the embodiment, the semiconductor light emitting device 150 as shown in FIG. 12 can be manufactured using the process shown in FIGS. 13 to 17. That is, a plurality of growth holes 510 can be formed on the wafer 501 (FIGS. 15A and 15B), and the light emitting structure 160 can be grown within the plurality of growth holes 510. Thereafter, the insulating film 503 can be removed and the plurality of light emitting structures can be separated from the wafer 501, so that a plurality of semiconductor light emitting devices 150 can be manufactured.

In the embodiment, since the diameter and/or depth of each of the plurality of growth holes 510 is the same, the diameter and/or length of each of the plurality of light emitting portions 160 grown from the plurality of growth holes 510 can be also the same.

When a display is implemented using a plurality of semiconductor light emitting devices having the same diameter, the luminance of each pixel can be the same, so that the image quality can be improved by eliminating the luminance difference between pixels. In addition, when a display is implemented using a plurality of semiconductor light emitting devices having the same length, as shown in FIG. 30, all of the plurality of semiconductor light emitting devices 150B can be electrically connected to the wiring electrodes 330 and 340, thereby preventing lighting defects.

According to the embodiment, the semiconductor light emitting device 150A as shown in FIGS. 18 and 19 can be manufactured using the process shown in FIGS. 20 to 28. That is, after growing the light emitting structure 160 in the plurality of growth holes 510 on the wafer 501, a part of the upper side of the insulating film 503 can be removed (FIG. 24). Thereafter, after the metal film is formed, an etching process can be performed until all of the metal film on the removed insulating film is removed, so that the upper electrodes 156 and 157 can be formed (FIGS. 25 and 26). Thereafter, the insulating film 503 can be removed by performing an etching process using the upper electrodes 156 and 157 as masks, so that that the insulating film 503 overlapping the upper electrodes 156 and 157 may be not removed to become the insulating layer 155 (FIGS. 27 and 28). Thereafter, the lower electrode 158 can be formed on the opposite side of the upper electrodes 156 and 157 in the light emitting structure 160, so that that a semiconductor light emitting device can be manufactured.

Therefore, during the manufacturing process of the light emitting structure 160, the upper electrodes 156 and 157 and the lower electrode 158 as well as the insulating layer 155 can be formed, and a separate electrode can be formed after the light emitting structure 160 is manufactured. Since there is no need to form an insulating layer, the process can be simple and material costs can be reduced.

Additional scope of applicability of the embodiments will become apparent from the detailed description below. However, since various changes and modifications within the spirit and scope of the embodiments can be clearly understood by those skilled in the art, the detailed description and specific embodiments, such as preferred embodiments, should be understood as being given by way of example only.

### DESCRIPTION OF DRAWINGS

FIG. 1 shows light emitting diodes mounted on a substrate to implement a display in the related art.

FIG. 2 shows the living room of a house where a display device 100 according to an embodiment is disposed.

FIG. 3 is a block diagram schematically showing a display device according to an embodiment.

FIG. 4 is a circuit diagram showing an example of the pixel of FIG. 3.

FIG. 5 is a plan view showing the display panel of FIG. 3 in detail.

FIG. 6 is an enlarged view of a first panel area in the display device of FIG. 2.

FIG. 7 is an enlarged view of area A2 in FIG. 6.

FIG. 8 is a diagram showing an example in which a light emitting device according to an embodiment is assembled on a substrate by a self-assembly method.

FIGS. 9 and 10 are diagrams showing an example in which a light emitting device according to an embodiment is transferred to a substrate by a transfer method.

FIG. 11 is a cross-sectional view schematically showing the display panel of FIG. 3.

FIG. 12 is a cross-sectional view showing a semiconductor light emitting device according to a first embodiment.

FIGS. 13 to 17 show the manufacturing process of a semiconductor light emitting device according to the first embodiment.

FIG. 18 is a cross-sectional view showing a semiconductor light emitting device according to a second embodiment.

FIG. 19 is a cross-sectional view showing the light emitting structure of FIG. 18 in detail.

FIGS. 20 to 28 show the manufacturing process of a semiconductor light emitting device according to the second embodiment.

FIG. 29 is a cross-sectional view showing a semiconductor light emitting device according to a third embodiment.

FIG. 30 is a plan view showing a display device according to an embodiment.

FIG. 31 is a cross-sectional view showing a display device according to an embodiment.

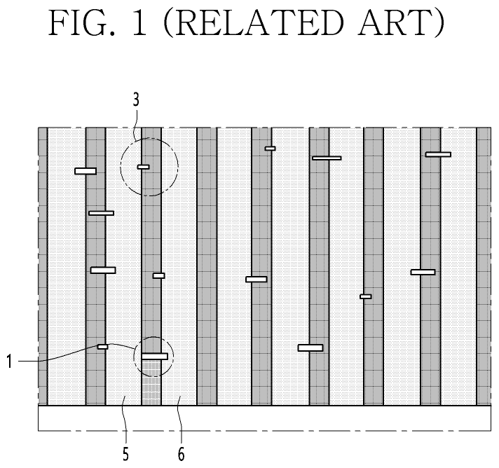

### MODE FOR INVENTION

Hereinafter, the embodiment disclosed in this specification will be described in detail with reference to the accompanying drawings, but the same or similar components are given the same reference numerals regardless of reference numerals, and redundant descriptions thereof will be omitted. The suffixes ‘module’ and ‘unit’ for the components used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification may be not limited by the accompanying drawings. Also, when a component such as a layer, region or substrate is referred to as being ‘on’ another component, this means that there can be directly on the other component or be other intermediate components therebetween.

The display device described in this specification comprise a mobile phone, a smart phone, a laptop computer, a digital broadcasting terminal, a personal digital assistant (PDA), a portable multimedia player (PMP), a navigation, a slate personal computer (PC), a tablet PC, an ultra-book, a digital TV, a desktop computer, etc. However, the configuration according to the embodiment described in this specification can be applied to a device capable of displaying even if it is a new product type that is developed in the future.

Hereinafter, a light emitting device according to an embodiment and a display device comprising the same will be described.

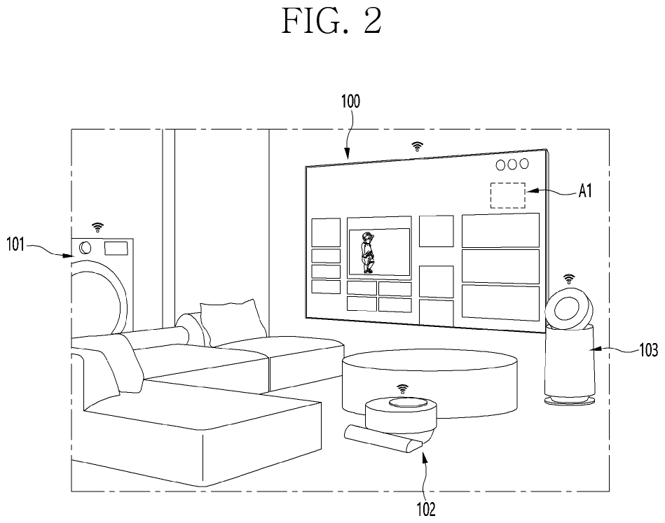

FIG. 2 shows the living room of a house where a display device 100 according to an embodiment is disposed.

The display device 100 of the embodiment can display the status of various electronic products such as a washing machine 101, a robot cleaner 102, and an air purifier 103, can communicate with each electronic product based on an internet of things (IoT), can control each electronic product based on the user's setting data.

The display device 100 according to the embodiment can comprise a flexible display manufactured on a thin and flexible substrate. The flexible display can bend or curl like paper while maintaining the characteristics of existing flat displays.

In the flexible display, visual information can be implemented by independently controlling the light emission of unit pixels arranged in a matrix form. An unit pixel refers to the minimum unit for implementing one color. The unit pixel of the flexible display can be implemented by a light emitting device. In the embodiment, the light emitting device can be a micro-LED or nano-LED, but is not limited thereto.

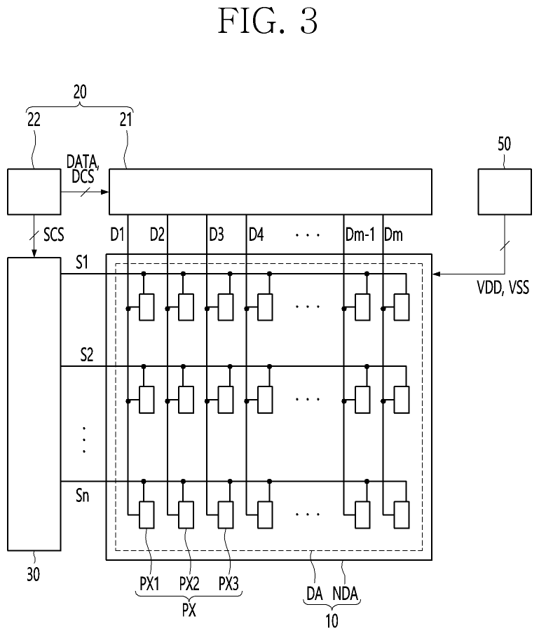

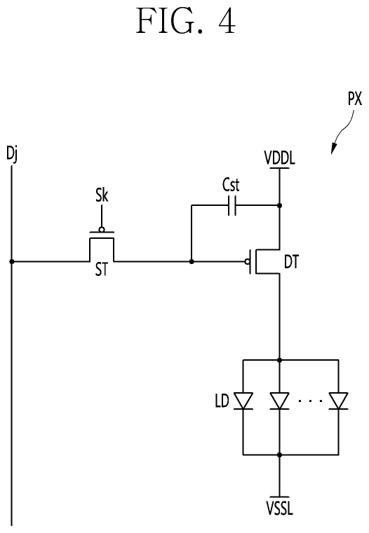

FIG. 3 is a block diagram schematically showing a display device according to an embodiment, and FIG. 4 is a circuit diagram showing an example of the pixel of FIG. 3.

Referring to FIGS. 3 and 4, a display device according to an embodiment can comprise a display panel 10, a driving circuit 20, a scan driving device 30, and a power supply circuit 50.

The display device 100 of the embodiment can drive the light emitting device in an active matrix (AM) method or a passive matrix (PM) method.

The driving circuit 20 can comprise a data driving device 21 and a timing controller 22.

The display panel 10 can be rectangular, but is not limited thereto. That is, the display panel 10 can be formed in a circular or oval shape. At least one side of the display panel 10 can be bent to a predetermined curvature.

The display panel 10 can be divided into a display area DA and a non-display area NDA disposed around the display area DA. The display area DA is an area where pixels PX can be formed to display an image. The display panel 10 can comprise data lines (D1 to Dm, m is an integer greater than 2), scan lines (S1 to Sn, n is an integer greater than 2) that intersect the data lines D1 to Dm, a high potential voltage line supplied with high potential voltage, a low potential voltage line supplied with low potential voltage, and pixels PX connected to the data lines D1 to Dm and the scan lines S1 to Sn.

Each of the pixels PX can comprise a first sub-pixel PX1, a second sub-pixel PX2, and a third sub-pixel PX3. The first sub-pixel PX1 can emit a first color light of a first main wavelength, the second sub-pixel PX2 can emit a second color light of a second main wavelength, and the third sub-pixel PX3 can emit a third color light of a third main wavelength. The first color light can be red light, the second color light can be green light, and the third color light can be blue light, but are not limited thereto. Additionally, in FIG. 3, it is illustrated that each of the pixels PX can comprise three sub-pixels, but is not limited thereto. That is, each pixel PX can comprise four or more sub-pixels.

The first sub-pixel PX1, the second sub-pixel PX2, and the third sub-pixel PX3 each can be connected to at least one of the data lines D1 to Dm, at least one of the scan lines S1 to Sn, and the high potential voltage line. As shown in FIG. 4, the first sub-pixel PX1 can comprise light emitting devices LD, a plurality of transistors for supplying current to the light emitting devices LD, and at least one capacitor Cst.

Although not shown in the drawing, each of the first sub-pixel PX1, the second sub-pixel PX2, and the third sub-pixel PX3 can comprise only one light emitting device LD and at least one capacitor Cst.

Each of the light emitting devices LD can be a semiconductor light emitting diode comprising a first electrode, a plurality of conductivity type semiconductor layers, and a second electrode. Here, the first electrode can be an anode electrode and the second electrode can be a cathode electrode, but is not limited thereto.

As shown in FIG. 6, the plurality of transistors can comprise a driving transistor DT that supplies current to the light emitting devices LD and a scan transistor ST that supplies a data voltage to the gate electrode of the driving transistor DT. The driving transistor DT can comprise a gate electrode connected to a source electrode of the scan transistor ST, a source electrode connected to a high potential voltage line to which a high potential voltage is applied, and a drain electrode connected to the first electrodes of the light emitting devices LD. The scan transistor ST can comprise a gate electrode connected to the scan line (Sk, k is an integer satisfying 1≤k≤n), a source electrode connected to the gate electrode of the driving transistor DT, and a drain electrode connected to a data line (Dj, j is an integer satisfying 1≤j≤m.

The capacitor Cst is formed between the gate electrode and the source electrode of the driving transistor DT. The storage capacitor Cst charges the difference between the gate voltage and source voltage of the driving transistor DT.

The driving transistor DT and the scan transistor ST can be formed of a thin film transistor. In addition, in FIG. 6, the driving transistor DT and the scan transistor ST are mainly described as being formed of a P-type metal oxide semiconductor field-effect transistor (MOSFET), but is not limited thereto. The driving transistor DT and the scan transistor ST can be formed of an N-type MOSFET. In this instance, the positions of the source and drain electrodes of each of the driving transistor DT and scan transistor ST can be changed.

In addition, in FIG. 4, it is illustrated in which each of the first sub-pixel PX1, the second sub-pixel PX2, and the third sub-pixel PX3 has one driving transistor DT, one scan transistor ST, and one capacitor Cst, but is not limited thereto. Each of the first sub-pixel PX1, the second sub-pixel PX2, and the third sub-pixel PX3 can comprise a plurality of scan transistors ST and a plurality of capacitors Cst.

Since the second sub-pixel PX2 and the third sub-pixel PX3 can be represented by substantially the same circuit diagram as the first sub-pixel PX1, detailed descriptions thereof will be omitted.

The driving circuit 20 outputs signals and voltages for driving the display panel 10. For this purpose, the driving circuit 20 can comprise a data driving device 21 and a timing controller 22.

The data driving device 21 receives digital video data DATA and source control signal DCS from the timing controller 22. The data driving device 21 converts digital video data DATA into analog data voltages according to the source control signal DCS and supplies them to the data lines D1 to Dm of the display panel 10.

The timing controller 22 receives digital video data DATA and timing signals from the host system. The timing signals can comprise a vertical synchronization signal, a horizontal synchronization signal, a data enable signal, and a dot clock. The host system can be an application processor in a smartphone or tablet PC, a monitor, or a system-on-chip in a TV.

The timing controller 22 generates control signals to control the operation timing of the data driving device 21 and the scan driving device 30. The control signals can comprise a source control signal DCS for controlling the operation timing of the data driving device 21 and a scan control signal SCS for controlling the operation timing of the scan driving device 30.

The driving circuit 20 can be disposed in the non-display area NDA provided on one side of the display panel 10. The driving circuit 20 can be formed of an integrated circuit IC and mounted on the display panel 10 using a chip on glass COG method, a chip on plastic COP method, or an ultrasonic bonding method, but is not limited to thereto. For example, the driving circuit 20 can be mounted on a circuit board (not shown) rather than on the display panel 10.

The data driving device 21 can be mounted on the display panel 10 using a COG method, a COP method, or an ultrasonic bonding method, and the timing control unit 22 can be mounted on a circuit board.

The scan driving device 30 receives a scan control signal SCS from the timing controller 22. The scan driving device 30 generates scan signals according to the scan control signal SCS and supplies them to the scan lines S1 to Sn of the display panel 10. The scan driving device 30 can comprise a plurality of transistors and can be formed in the non-display area NDA of the display panel 10. Alternatively, the scan driving device 30 can be formed as an integrated circuit, and in this instance, can be mounted on a gate flexible film attached to the other side of the display panel 10.

The circuit board can be attached to pads provided at one edge of the display panel 10 using an anisotropic conductive film. For this reason, the lead lines of the circuit board can be electrically connected to the pads. The circuit board can be a flexible printed circuit board, a printed circuit board, or a flexible film such as a chip on film. The circuit board can be bent toward the lower side of the display panel 10. For this reason, one side of the circuit board can be attached to one edge of the display panel 10, and the other side can be disposed on the lower side the display panel 10 and can be connected to a system board on which the host system is mounted.

The power supply circuit 50 can generate voltages necessary for driving the display panel 10 from the main power supplied from the system board and supply them to the display panel 10. For example, the power supply circuit 50 can generate a high potential voltage VDD and a low potential voltage VSS for driving the light emitting devices LD of the display panel 10 from the main power supply to supply the high potential voltage VDD and the low potential voltage VSS to high potential voltage line and low potential voltage line. Additionally, the power supply circuit 50 can generate and supply driving voltages for driving the driving circuit 20 and the scan driving device 30 from the main power supply.

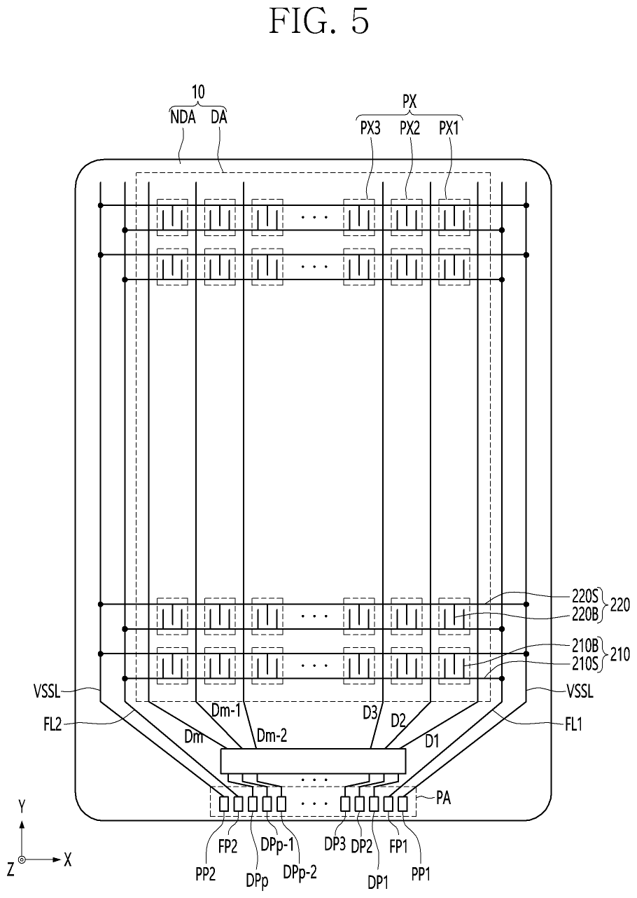

FIG. 5 is a plan view showing the display panel of FIG. 3 in detail. In FIG. 5, for convenience of explanation, data pads (DP1 to DPp, p is an integer of 2 or more), the floating pads FP1 and FP2, the power pads PP1 and PP2, the floating lines FL1 and FL2, the low potential voltage line VSSL, the data lines D1 to Dm, the first pad electrodes 210, and the second pad electrodes 220 are shown.

Referring to FIG. 5, the data lines D1 to Dm, the first pad electrodes 210, the second pad electrodes 220, and the pixels PX can be disposed in the display area DA of the display panel 10.

The data lines D1 to Dm can extend long in the second direction (Y-axis direction). One side of the data lines D1 to Dm can be connected to the driving circuit (20 in FIG. 5). For this reason, the data voltages of the driving circuit 20 can be applied to the data lines D1 to Dm.

The first pad electrodes 210 can be disposed to be spaced apart at predetermined distance in the first direction (X-axis direction). For this reason, the first pad electrodes 210 may not overlap the data lines D1 to Dm. Among the first pad electrodes 210, the first pad electrodes 210 disposed at the right edge of the display area DA can be connected to the first floating line FL1 in the non-display area NDA. Among the first pad electrodes 210, the first pad electrodes 210 disposed at the left edge of the display area DA can be connected to the second floating line FL2 in the non-display area NDA.

Each of the second pad electrodes 220 can extend long in the first direction (X-axis direction). For this reason, the second pad electrodes 220 can overlap the data lines D1 to Dm. Additionally, the second pad electrodes 220 can be connected to the low potential voltage line VSSL in the non-display area NDA. For this reason, the low potential voltage of the low potential voltage line VSSL can be applied to the second pad electrodes 220.

A pad portion PA, the driving circuit 20, the first floating line FL1, the second floating line FL2, and the low potential voltage line VSSL can be disposed in the non-display area NDA of the display panel 10. The pad portion PA can comprise the data pads DP1 to DPp, the floating pads FP1 and FP2, and the power pads PP1 and PP2.

The pad portion PA can be disposed at one edge of the display panel 10, for example, at the lower edge. The data pads DP1 to DPp, the floating pads FP1 and FP2, and the power pads PP1 and PP2 can be disposed side by side in the first direction (X-axis direction) in the pad portion PA.

A circuit board can be attached to the data pads DP1 to DPp, the floating pads FP1 and FP2, and the power pads PP1 and PP2 using an anisotropic conductive film. For this reason, the circuit board, the data pads DP1 to DPp, the floating pads FP1 and FP2, and the power pads PP1 and PP2 can be electrically connected.

The driving circuit 20 can be connected to the data pads DP1 to DPp through link lines. The driving circuit 20 can receive digital video data DATA and timing signals through the data pads DP1 to DPp. The driving circuit 20 can convert digital video data DATA into analog data voltages and supply them to the data lines D1 to Dm of the display panel 10.

The low potential voltage line VSSL can be connected to the first power pad PP1 and the second power pad PP2 of the pad portion PA. The low potential voltage line VSSL can extend long in the second direction (Y-axis direction) from the non-display area NDA outside the left and right sides of the display area DA. The low potential voltage line VSSL can be connected to the second pad electrode 220. For this reason, the low potential voltage of the power supply circuit 50 can be applied to the second pad electrode 220 through the circuit board, the first power pad PP1, the second power pad PP2, and the low potential voltage line VSSL.

The first floating line FL1 can be connected to the first floating pad FP1 of the pad portion PA. The first floating line FL1 can extend long in the second direction (Y-axis direction) from the non-display area NDA outside the left and right sides of the display area DA. The first floating pad FP1 and the first floating line FL1 can be dummy pads and dummy lines to which no voltage is applied.

The second floating line FL2 can be connected to the second floating pad FP2 of the pad portion PA. The first floating line FL1 can extend long in the second direction (Y-axis direction) from the non-display area NDA outside the left and right sides of the display area DA. The second floating pad FP2 and the second floating line FL2 can be dummy pads and dummy lines to which no voltage is applied.

Meanwhile, since the light emitting devices (LD in FIG. 6) have a very small size, it is very difficult to mount the light emitting elements LD into the first sub-pixel PX1, the second sub-pixel PX2, and the third sub-pixel PX3 of each of the pixels PX.

To solve this problem, an alignment method using dielectrophoresis method was proposed.

That is, in order to align the light emitting devices (150 in FIG. 6) during the manufacturing process of the display panel 10, an electric field can be formed in the first sub-pixel PX1, the second sub-pixel PX2, and the third sub-pixel PX3 of each of the pixels PX. Specifically, during the manufacturing process, a dielectrophoretic force can be applied to the light emitting devices 310, 320, and 330 using a dielectrophoresis method, so that that the light emitting elements 310, 320, and 330 can be aligned in each of the first sub-pixel PX1, the second sub-pixel PX2, and the third sub-pixel PX3.

However, during the manufacturing process, it is difficult to drive the thin film transistors and apply a ground voltage to the first pad electrodes 210.

Therefore, in the completed display device, the first pad electrodes 210 can be disposed to be spaced apart at predetermined distance in the first direction (X-axis direction), but during the manufacturing process, the first pad electrodes 210 may be not disconnected in the first direction (X-axis direction) but can be disposed to extend long.

For this reason, the first pad electrodes 210 can be connected to the first floating line FL1 and the second floating line FL2 during the manufacturing process. Therefore, the first pad electrodes 210 can receive the ground voltage through the first floating line FL1 and the second floating line FL2. Therefore, after aligning the light emitting devices 310, 320, and 330 using a dielectrophoresis method during the manufacturing process, the first pad electrodes 210 can be disconnected, so that that the first pad electrodes 210 can be disposed to be spaced apart at predetermined distance in the first direction (X-axis direction).

Meanwhile, the first floating line FL1 and the second floating line FL2 can be lines for applying the ground voltage during the manufacturing process, and no voltage can be applied in the completed display device. Alternatively, in the completed display device, the ground voltage can be applied to the first floating line FL1 and the second floating line FL2 to prevent static electricity or to drive the light emitting devices 310, 320, and 330.

FIG. 6 is an enlarged view of a first panel area in the display device of FIG. 2.

According to FIG. 6, the display device 100 of the embodiment can be manufactured by mechanically and electrically connecting a plurality of panel areas, such as the first panel area A1, by tiling.

The first panel area A1 can comprise a plurality of light emitting devices 150 disposed for each unit pixel (PX in FIG. 5).

For example, the unit pixel PX can comprise a first sub-pixel PX1, a second sub-pixel PX2, and a third sub-pixel PX3. For example, a plurality of red light emitting devices 150R can be disposed in the first sub-pixel PX1, a plurality of green light emitting devices 150G can be disposed in the second sub-pixel PX2, and a plurality of blue light emitting devices 150B can be disposed in the third sub-pixel PX3. The unit pixel PX can further comprise a fourth sub-pixel in which no light emitting device is disposed, but is not limited thereto.

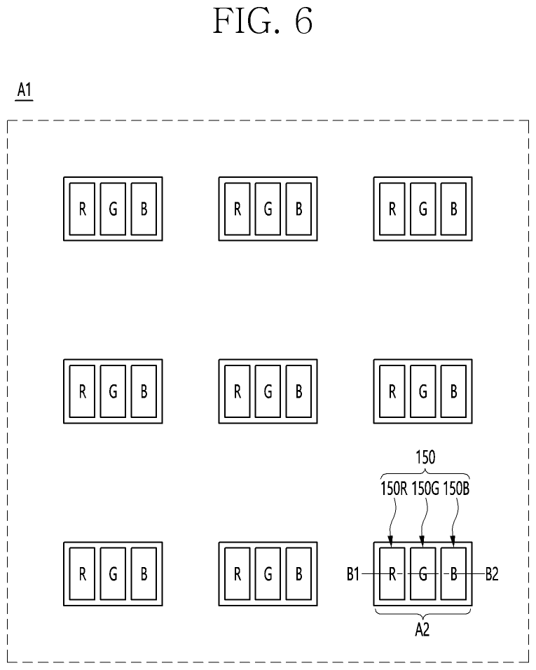

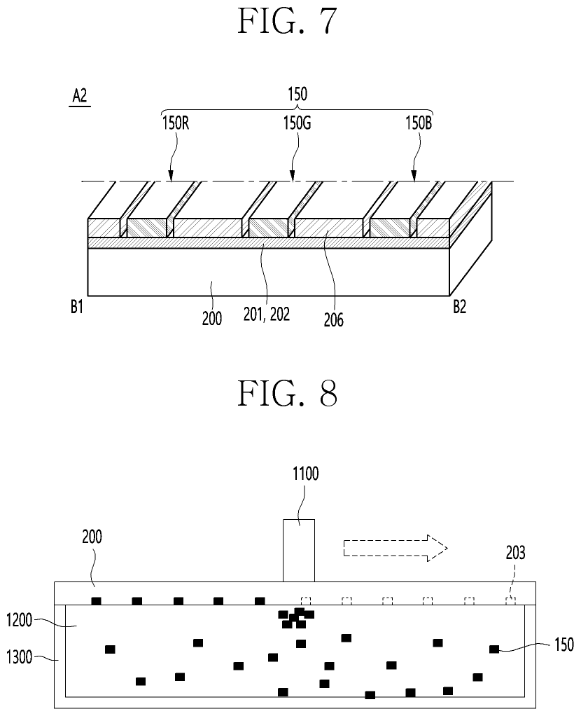

FIG. 7 is an enlarged view of area A2 in FIG. 6.

Referring to FIG. 7, the display device 100 of the embodiment can comprise a substrate 200, assembling wirings 201 and 202, an insulating layer 206, and a plurality of light emitting devices 150. More components can be included than these.

The assembling wiring can comprise a first assembling wiring 201 and a second assembling wiring 202 that are spaced apart from each other. The first assembling wiring 201 and the second assembling wiring 202 can be provided to generate dielectrophoretic force to assemble the light emitting device 150.

The light emitting device 150 can comprise, but is not limited thereto, a red light emitting device 150, a green light emitting device 150G, and a blue light emitting device 150B0 to form an unit sub-pixel, and it is also possible to implement red and green colors by using red phosphors and green phosphors, respectively.

The substrate 200 can be formed of glass or polyimide. Additionally, the substrate 200 can comprise a flexible material such as polyethylene naphthalate (PEN) or polyethylene terephthalate (PET). Additionally, the substrate 200 can be made of a transparent material, but is not limited thereto.

The insulating layer 206 can comprise an insulating and flexible material such as polyimide, PEN, PET, etc., and can be integrated with the substrate 200 to form one substrate.

The insulating layer 206 can be a conductive adhesive layer that has adhesiveness and conductivity, and the conductive adhesive layer can be flexible and enable a flexible function of the display device. For example, the insulating layer 206 can be an anisotropic conductive film (ACF) or a conductive adhesive layer such as an anisotropic conductive medium or a solution comprising conductive particles. The conductive adhesive layer can be a layer that is electrically conductive in a direction perpendicular to the thickness, but electrically insulating in a direction horizontal to the thickness.

The insulating layer 206 can comprise an assembly hole 203 into which the light emitting device 150 is inserted. Therefore, during self-assembly, the light emitting device 150 can be easily inserted into the assembly hole 203 of the insulating layer 206. The assembly hole 203 can be called an insertion hole, a fixing hole, an alignment hole, etc.

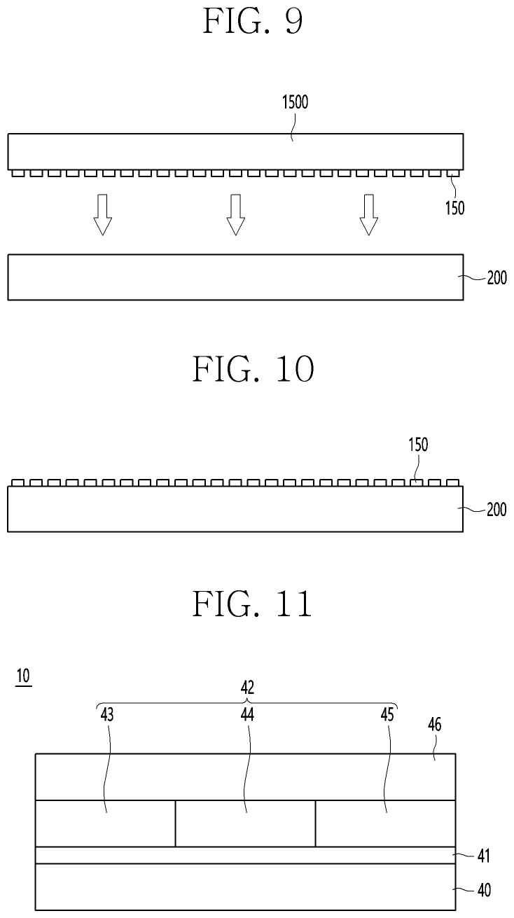

Meanwhile, methods of mounting the light emitting device 150 on the substrate 200 can comprise, for example, a self-assembly method (FIG. 8) and a transfer method (FIGS. 9 and 10).

FIG. 8 is a diagram showing an example in which a light emitting device according to an embodiment is assembled on a substrate by a self-assembly method.

The self-assembly method of the light emitting device will be described with reference to FIGS. 7 and 8.

The substrate 200 can be a panel substrate of a display device. In the following description, the substrate 200 will be described as a panel substrate of a display device, but the embodiment is not limited thereto.

The substrate 200 can be formed of glass or polyimide. Additionally, the substrate 200 can comprise a flexible material such as PEN or PET. Additionally, the substrate 200 can be made of a transparent material, but is not limited thereto.

Referring to FIG. 8, the light emitting device 150 can be inserted into the chamber 1300 filled with the fluid 1200. The fluid 1200 can be water such as ultrapure water, but is not limited thereto. The chamber can be called a water tank, container, vessel, etc.

After this, the substrate 200 can be disposed on the chamber 1300. Depending on the embodiment, the substrate 200 can be input into the chamber 1300.

As shown in FIG. 7, a pair of assembling wirings 201 and 202 corresponding to each of the light emitting devices 150 to be assembled can be disposed on the substrate 200.

The assembling wirings 201 and 202 can be formed of transparent electrodes (ITO) or can comprise a metal material with excellent electrical conductivity. For example, the assembling wirings 201 and 202 can be formed of at least one of titanium (Ti), chromium (Cr), nickel (Ni), aluminum (Al), platinum (Pt), gold (Au), tungsten (W), and molybdenum (Mo) or an alloy thereof.

An electric field can be formed in the assembling wirings 201 and 202 by an externally-supplied voltage, and a dielectrophoretic force can be formed between the assembling wirings 201 and 202 by the electric field. The light emitting device 150 can be fixed to the assembly hole 203 on the substrate 200 by this dielectrophoretic force.

The distance between the assembling wirings 201 and 202 can be formed to be smaller than the width of the light emitting device 150 and the width of the assembly hole 203, so that that the assembly position of the light emitting device 150 using an electric field can be fixed more precisely.

An insulating layer 206 can be formed on the assembling wirings 201 and 202 to protect the assembling wirings 201 and 202 from the fluid 1200 and prevent leakage of current flowing through the assembling wirings 201 and 202. The insulating layer 206 can be formed as a single layer or multilayer of an inorganic insulator such as silica or alumina or an organic insulator.

Additionally, the insulating layer 206 can comprise an insulating and flexible material such as polyimide, PEN, PET, etc., and can be integrated with the substrate 200 to form one substrate.

The insulating layer 206 can be an adhesive insulating layer or a conductive adhesive layer with conductivity. The insulating layer 206 can be flexible and can enable flexible functions of the display device.

The insulating layer 206 has a barrier rib, and the assembly hole 203 can be formed by this barrier rib. For example, when forming the substrate 200, a part of the insulating layer 206 can be removed, so that that each of the light emitting devices 150 can be assembled into an assembly hole 203 of the insulating layer 206.

The assembly hole 203 in which the light emitting devices 150 are coupled can be formed in the substrate 200, and the surface where the assembly hole 203 is formed can be in contact with the fluid 1200. The assembly hole 203 can guide the exact assembly position of the light emitting device 150.

Meanwhile, the assembly hole 203 can have a shape and size corresponding to the shape of the light emitting device 150 to be assembled at the corresponding position. Accordingly, it is possible to prevent another light emitting device from being assembled in the assembly hole 203 or a plurality of light emitting devices from being assembled in the assembly hole 203.

Referring again to FIG. 8, after the substrate 200 is disposed, the assembly device 1100 comprising a magnetic material can move along the substrate 200. For example, a magnet or electromagnet can be used as a magnetic material. The assembly device 1100 can move while in contact with the substrate 200 in order to maximize the area to which the magnetic field is applied within the fluid 1200. Depending on the embodiment, the assembly device 1100 can comprise a plurality of magnetic materials or a magnetic material of a size corresponding to that of the substrate 200. In this instance, the moving distance of the assembly device 1100 can be limited to within a predetermined range.

The light emitting device 150 in the chamber 1300 can move toward the assembly device 1100 by the magnetic field generated by the assembly device 1100.

While moving toward the assembly device 1100, the light emitting device 150 can enter the assembly hole 203 and come into contact with the substrate 200.

At this time, by the electric field applied by the assembling wiring 201 and 202 formed on the substrate 200, the light emitting element 150 in contact with the substrate 200 can be prevented from being separated by movement of the assembly device 1100.

In other words, the time required for each of the light emitting devices 150 to be assembled on the substrate 200 can be drastically shortened by the self-assembly method using the electromagnetic field described above, so that that large-area and high-pixel display can be implemented more quickly and economically.

A predetermined solder layer 225 can be further formed between the light emitting device 150 and the second pad electrode 222 assembled on the assembly hole 203 of the substrate 200 to improve the bonding force of the light emitting device 150.

Thereafter, the first pad electrode 221 can be connected to the light emitting device 150 and power can be applied to the light emitting device 150.

Next, the molding layer 230 can be formed on the barrier rib 200S and the assembly hole 203 of the substrate 200. The molding layer 230 can be transparent resin or resin comprising a reflective material or a scattering material.

FIGS. 9 and 10 are diagrams showing an example in which a light emitting device according to an embodiment is transferred to a substrate by a transfer method.

As shown in FIG. 9, a plurality of light emitting devices 150 can be attached to the substrate 1500. For example, the substrate 1500 can be a donor substrate that serves as an intermediate medium for mounting the light emitting devices 150 on the display substrate. In this instance, the plurality of light emitting devices 150 manufactured on the wafer can be attached to the substrate 1500, and the plurality of light emitting devices 150 attached on the substrate 1500 can be transferred onto the display substrate.

Hereinafter, the substrate 1500 will be described as a donor substrate, but the substrate 1500 can be a display substrate on which the plurality of light emitting devices 150 are directly transferred without passing through the donor substrate.

As shown in FIG. 9, after the substrate 1500 is positioned on the display substrate 200, an alignment process can be performed so that each of the plurality of light emitting devices 150 on the substrate 1500 can correspond to each pixel of the display substrate 200.

Thereafter, by pressing the substrate 1500 (or the display substrate 200), the plurality of light emitting elements 150 on the substrate 1500 can be transferred to each pixel on the display substrate 200, as shown in FIG. 10.

Afterwards, a plurality of light emitting devices 150 can be attached to the display substrate 200 through a post-process and the plurality of light emitting devices 150 can be electrically connected to a power source, so that that the plurality of light emitting devices 150 can emit light to display an image.

Meanwhile, the display device according to the embodiment can display an image using a light emitting device. The light emitting device of the embodiment is a self-emissive element that emits light by itself by applying electricity, and can be a semiconductor light emitting device. Since the light emitting device of the embodiment is made of an inorganic semiconductor material, it can be resistant to deterioration and can have a semi-permanent lifespan, so that it can provide stable light and can contribute to display devices realizing high-quality and high-definition images.

For example, a display device can use a light emitting device as a light source and can have a color generator on the light emitting device, so that images can be displayed using this color generator (FIG. 11).

Although not shown, the display device can display images through a display panel in which a plurality of light emitting devices that generate different color lights are disposed in pixels, respectively.

FIG. 11 is a cross-sectional view schematically showing the display panel of FIG. 5.

Referring to FIG. 11, the display panel 10 of the embodiment can comprise a first substrate 40, a light emitting structure 41, a color generator 42, and a second substrate 46. The display panel 10 of the embodiment can comprise more components than these, but is not limited thereto. The first substrate 40 can be the substrate 200 shown in FIG. 9.

Although not shown, at least one insulating layer can be disposed between the first substrate 40 and the light emitting structure 41, between the light emitting structure 41 and the color generator 42, and/or between the color generator 42 and the second substrate 46, but is not limited thereto.

The first substrate 40 can support the light emitting structure 41, the color generator 42, and the second substrate 46. The first substrate 40 can comprise various components as described above, such as the data lines (D1 to Dm, m is an integer of 2 or more), the scan lines S1 to Sn, the high potential voltage line, the low potential voltage line as shown in FIG. 6, a plurality of transistors ST and DT and at least one capacitor Cst as shown in FIG. 3, the first pad electrode 210 and the second pad 220 as shown in FIG. 7.

The first substrate 40 can be formed of glass or a flexible material, but is not limited thereto.

The light emitting structure 41 can provide light to the color generating unit 42. The light emitting structure 41 can comprise a plurality of light sources that emit light by themselves by applying electricity. For example, the light source can comprise a light emitting device (150 in FIG. 6).

As an example, the plurality of light emitting devices 150 can be disposed separately for each sub-pixel of the pixel and can emit light independently by controlling each sub-pixel.

As another example, the plurality of light emitting devices 150 can be disposed regardless of pixel division and emit light simultaneously from all sub-pixels.

The light emitting device 150 of the embodiment can emit blue light, but is not limited thereto. For example, the light emitting device 150 of the embodiment can emit white light or purple light.

Meanwhile, the light emitting device 150 can emit red light, green light, and blue light for each sub-pixel. For this purpose, for example, a red light emitting device that emits red light can be disposed in the first sub-pixel, that is, the red sub-pixel, a green light emitting device that emits green light can be disposed in the second sub-pixel, that is, the green sub-pixel, a blue light emitting device that emits blue light can be disposed in the third sub-pixel, that is, the blue sub-pixel.

For example, each of the red light emitting device, the green light emitting device, and the blue light emitting device can comprise the group II-VI element or the group III-V compound, but is not limited thereto. For example, the group III-V compound can be selected from the group consisting of: a binary compound selected from the group consisting of GaN, GaP, GaAs, GaSb, AlN, AlP, AlAs, AlSb, InN, InP, InAs, InSb, and the mixture thereof; a ternary compound selected from the group consisting of GaNP, GaNAs, GaNSb, GaPAs, GaPSb, AlInP, AlNP, AlNAs, AlNSb, AlPAs, AlPSb, InNP, InNAs, InNSb, InPAs, InPSb, GaAlNP, and mixtures thereof; and a quaternary compound selected from the group consisting of AlGalnP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the mixture thereof.

The color generator 42 can generate color light that is different from the light provided from the light emitter 41.

For example, the color generator 42 can comprise a first color generator 43, a second color generator 44, and a third color generator 45. The first color generator 43 can correspond to the first sub-pixel PX1 of the pixel, the second color generator 44 can correspond to the second sub-pixel PX2 of the pixel, and the third color generator 45 can correspond to the third sub-pixel PX3 of the pixel.

The first color generator 43 can generate the first color light based on the light provided from the light emitting structure 41, the second color generator 44 can generate the second color light based on the light provided from the light emitting structure 41, and the third color generator 45 can generate the third color light based on the light provided from the light emitter 41. For example, the first color generator 43 can output the blue light of the light emitter 41 as red light, the second color generator 44 can output the blue light of the light emitter 41 as green light, and the third color generator 45 can output the blue light of the light emitter 41 as it is.

As an example, the first color generator 43 can comprise a first color filter, the second color generator 44 can comprise a second color filter, and the third color generator 45 can comprise a third color filter.

The first color filter, the second color filter, and the third color filter can be formed of a transparent material that allows light to pass through.

For example, at least one of the first color filter, second color filter, and third color filter can comprise quantum dots.

The quantum dots of the example can be selected from group II-VI elements, group III-V compounds, group IV-VI compounds, group IV elements, group VI elements, and combinations thereof.

The group II-VI compound can be selected from the group consisting of a binary compound selected from the group consisting of CdSe, CdTe, ZnS, ZnSe, ZnTe, ZnO, HgS, HgSe, HgTe, MgSe, MgS, and the mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and the mixture thereof.

For example, the group III-V compound can be selected from the group consisting of: a binary compound selected from the group consisting of GaN, GaP, GaAs, GaSb, AlN, AIP, AlAs, AlSb, InN, InP, InAs, InSb, and the mixture thereof; a ternary compound selected from the group consisting of GaNP, GaNAs, GaNSb, GaPAs, GaPSb, AlInP, AlNP, AlNAs, AlNSb, AlPAs, AlPSb, InNP, InNAs, InNSb, InPAs, InPSb, GaAlNP, and the mixture thereof; and a quaternary compound selected from the group consisting of AlGaInP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the mixture thereof.

The group IV-VI compound can be selected from the group consisting of: a binary compound selected from the group consisting of SnS, SnSe, SnTe, PbS, PbSe, PbTe, and the mixture thereof; a ternary compound selected from the group consisting of SnSeS, SnSeTe, SnSTe, PbSeS, PbSeTe, PbSTe, SnPbS, SnPbSe, SnPbTe, and the mixture thereof; and a quaternary compound selected from the group consisting of SnPbSSe, SnPbSeTe, SnPbSTe, and the mixture thereof.

The group IV element can be selected from the group consisting of Si, Ge, and mixtures thereof. The group IV element can be a binary compound selected from the group consisting of SiC, SiGe, and mixtures thereof.

These quantum dots can have a full width of half maximum (FWHM) of the emission wavelength spectrum of approximately 45 nm or less, and light emitted through the quantum dots can be emitted in all directions. Accordingly, the viewing angle of the light emitting display device can be improved.

On the other hand, the quantum dots can have the form of nanoparticles, nanotubes, nanowires, nanofibers, nanoplate-shaped particles, etc. having spherical, pyramidal, multi-arm, or cubic shape, but is not limited to thereto.

For example, when the light emitting device 150 emits blue light, the first color filter can comprise red quantum dots, and the second color filter can comprise green quantum dots. The third color filter may not comprise quantum dots, but is not limited thereto. For example, the blue light from the light emitting device 150 can be absorbed by the first color filter, and the absorbed blue light can be wavelength shifted by the red quantum dots to output red light. For example, blue light from the light emitting device 150 can be absorbed by the second color filter, and the absorbed blue light can be wavelength shifted by the green quantum dots to output green light. For example, blue light from the foot and device can be absorbed by the third color filter, and the absorbed blue light can be emitted as it is.

Meanwhile, when the light emitting device 150 emits white light, not only the first color filter and the second color filter but also the third color filter can comprise quantum dots. That is, the white light of the light emitting device 150 can be wavelength shifted to blue light by the quantum dots comprised in the third color filter.

For example, at least one of the first color filter, the second color filter, and the third color filter can comprise a phosphor. For example, some of the first color filters, second color filters, and third color filters can comprise quantum dots, and other color filters can comprise phosphors. For example, each of the first color filter and the second color filter can comprise a phosphor and a quantum dot. For example, at least one of the first color filter, the second color filter, and the third color filter can comprise scattering particles. Since the blue light incident on each of the first color filter, the second color filter, and the third color filter is scattered by the scattering particles and the scattered blue light is color shifted by the corresponding quantum dot, light output efficiency can be improved.

As another example, the first color generator 43 can comprise a first color conversion layer and a first color filter. The second color generator 44 can comprise a second color converter and a second color filter. The third color generator 45 can comprise a third color conversion layer and a third color filter. Each of the first color conversion layer, the second color conversion layer, and the third color conversion layer can be disposed adjacent to the light emitting structure 41. The first color filter, second color filter, and third color filter can be disposed adjacent to the second substrate 46.

For example, the first color filter can be disposed between the first color conversion layer and the second substrate 46. For example, the second color filter can be disposed between the second color conversion layer and the second substrate 46. For example, the third color filter can be disposed between the third color conversion layer and the second substrate 46.

For example, the first color filter can be in contact with the upper surface of the first color conversion layer and have the same size as the first color conversion layer, but is not limited thereto. For example, the second color filter can be in contact with the upper surface of the second color conversion layer and can have the same size as the second color conversion layer, but is not limited thereto. For example, the third color filter can be in contact with the upper surface of the third color conversion layer and can have the same size as the third color conversion layer, but is not limited thereto.

For example, the first color conversion layer can comprise red quantum dots, and the second color conversion layer can comprise green quantum dots. The third color conversion layer may not comprise quantum dots. For example, the first color filter can comprise a red-based material that selectively transmits red light converted in the first color conversion layer, the second color filter can comprise a green material that selectively transmits green light converted in the second color conversion layer, and the third color filter can comprise a blue-based material that selectively transmits blue light transmitted as it is through the third color conversion layer.

Meanwhile, when the light emitting device 150 emits white light, not only the first color conversion layer and the second color conversion layer but also the third color conversion layer can comprise quantum dots. That is, the white light of the light emitting device 150 can be wavelength shifted to blue light by the quantum dots comprised in the third color filter.

Referring again to FIG. 11, the second substrate 46 can be disposed on the color generator 42 to protect the color generator 42. The second substrate 46 can be formed of glass, but is not limited thereto.

The second substrate 46 can be called a cover window, cover glass, etc.

The second substrate 46 can be formed of glass or a flexible material, but is not limited thereto.

The embodiment provides a plurality of semiconductor light emitting devices having the same size. That is, the sizes of a plurality of semiconductor light emitting devices manufactured on a wafer can be the same. Here, size can mean at least one of diameter and/or length (or height). The semiconductor light emitting device of the embodiment can have a minor axis and a major axis. The minor axis can be the diameter direction of the semiconductor light emitting device, and the major axis direction can be the longitudinal direction of the semiconductor light emitting device. Accordingly, in the semiconductor light emitting device of the embodiment, the length can be greater than the diameter. The semiconductor light emitting device of the embodiment can have a rod shape, but is not limited thereto. The semiconductor light emitting device of the embodiment can be a nano-scale semiconductor light emitting device, but is not limited thereto.

The semiconductor light emitting device of the example can be manufactured by growing in a growth hole previously formed in the form of a rod. The growth hole can correspond to the size of the semiconductor light emitting device. That is, the growth hole can have a diameter corresponding to the diameter of the semiconductor light emitting device and a depth corresponding to the length of the semiconductor light emitting device. A semiconductor light emitting device can be manufactured by growing a plurality of semiconductor layers in the growth hole through a growth process.

A plurality of growth holes are provided on the wafer, and a plurality of semiconductor layers are sequentially grown in the plurality of growth holes, so that that a plurality of semiconductor light emitting devices can be manufactured simultaneously. At this time, the plurality of growth holes can have the same diameter and depth. Accordingly, a plurality of semiconductor light emitting devices manufactured from a plurality of growth holes having the same diameter and depth can have the same size.

Conventionally, a plurality of semiconductor layers were sequentially grown on a wafer through a deposition process, and then a plurality of semiconductor light emitting devices were manufactured through an etching process. In this instance, not only does the plasma density differ depending on the position of the wafer during the etching process, but also etching is performed not only in the vertical direction but also in the horizontal direction due to the nature of the etching process, so that that the upper diameter of the plurality of semiconductor light emitting devices was smaller than the lower diameter, and the diameter of the active layer of each of the plurality of semiconductor light emitting devices was different depending on the position of the wafer. The light efficiency or light output of each semiconductor light emitting device was different depending on the diameter of the active layer. Therefore, when a display is implemented using a plurality of semiconductor light emitting devices, there is a problem that a difference in luminance occurs between each pixel, which leads to a decrease in image quality.

However, in the embodiment, a plurality of growth holes having the same depth and diameter can be prepared in advance on the wafer, and a plurality of semiconductor layers can be grown in these plurality of growth holes using a deposition process, so that a plurality of semiconductor light emitting devices having shapes corresponding to each growth hole can be manufactured. The plurality of manufactured semiconductor light emitting devices can have the same diameter and/or length regardless of the position of the wafer. The diameter of the semiconductor light emitting device can be the same as the diameter of the growth hole. The length of the semiconductor light emitting device may be equal to the depth of the growth hole.

Accordingly, in the embodiment, a plurality of semiconductor layers can be grown in the growth holes even if the density of the wafer is different during the plasma process, so that the semiconductor light emitting devices obtained from each of the plurality of growth holes can have the same diameter and/or length.

Here, the length can be a length at which both ends of the semiconductor light emitting device can be electrically contacted with each of the assembling wirings disposed to be spaced apart from each other on the display substrate. If the length of the semiconductor light emitting device is shortened, the shortened semiconductor light emitting device does not emit light because it is not in electrical contact with one of the assembling wirings. However, as in the embodiment, each of the semiconductor light emitting devices manufactured on the wafer can have a length that can electrically contact all of the assembling wirings, so that lighting defects can be minimized.

Meanwhile, in the embodiment, since the plurality of semiconductor light emitting devices manufactured in the plurality of growth holes of the wafer all have the same diameter, the same light efficiency or light output can be obtained. Therefore, when a display is implemented using a plurality of semiconductor light emitting devices manufactured on a wafer, image quality can be improved because there is no luminance difference between each pixel. Each pixel may be provided with at least one semiconductor light emitting device.

Meanwhile, the inner surface of the growth hole can have a plane perpendicular to the bottom surface. Accordingly, the side surface of the semiconductor light emitting device manufactured within the growth hole can have a plane perpendicular to the lower or upper surface of the semiconductor light emitting device.

The inner surface of the growth hole can have a smooth plane, that is, a plane with minimal roughness. Accordingly, since the side surface of the semiconductor light emitting device manufactured within the growth hole has a smooth plane, roughness can be improved.

Meanwhile, in the related art, a plurality of semiconductor layers were grown through a growth process, and individual semiconductor light emitting devices were manufactured through a dry etching process. During the dry etching process, the plasma density is different for each location on the wafer and the nano-scale patterns formed for the etching process are different, so that the sizes (diameters and/or lengths) of the plurality of semiconductor light emitting devices manufactured on the wafer are different from each other. Therefore, when a plurality of semiconductor light emitting devices having different sizes are mounted on a display substrate, there is a problem that semiconductor light emitting devices that do not contact the electrodes on the display substrate do not light up.

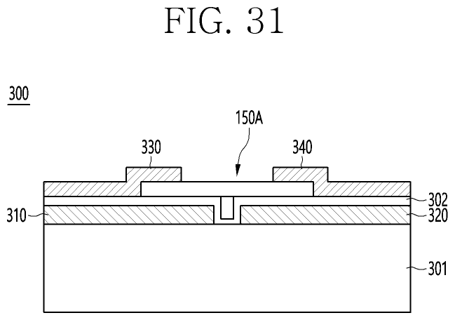

According to an embodiment, since a plurality of semiconductor light emitting devices manufactured on a wafer have the same size, when the plurality of semiconductor light emitting devices are mounted on a display substrate (301 in FIG. 31), lighting is possible in all pixels, preventing lighting defects.

Additionally, according to the embodiment, since the plurality of semiconductor light emitting devices have the same size, each of the plurality of semiconductor light emitting devices can have the same luminance. Therefore, when a plurality of semiconductor light emitting devices are mounted on the display substrate 301, uniform luminance can be obtained in all pixels, and image quality can be improved.

Meanwhile, in the related art, semiconductor light emitting devices were manufactured through a growth process and an etching process, and then electrodes were formed through a separate process, and then an insulating layer was formed through a separate process. According to an embodiment, an electrode or an insulating layer is formed during the manufacturing process of a semiconductor light emitting device, and there is no need to form a separate electrode or insulating layer after the semiconductor light emitting device is manufactured, thereby dramatically shortening the manufacturing process.

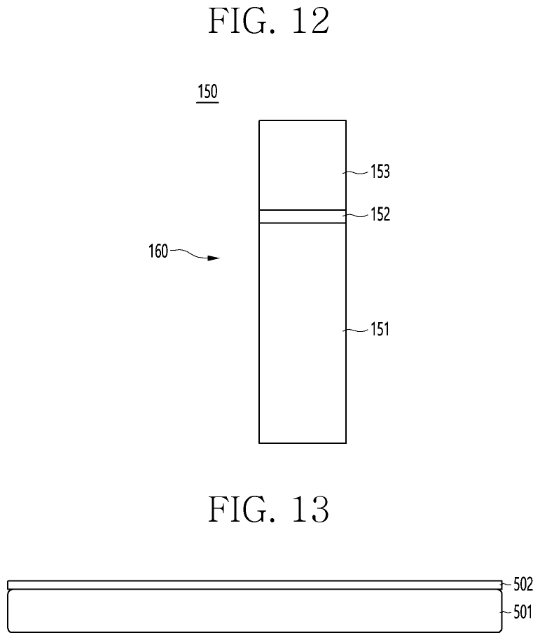

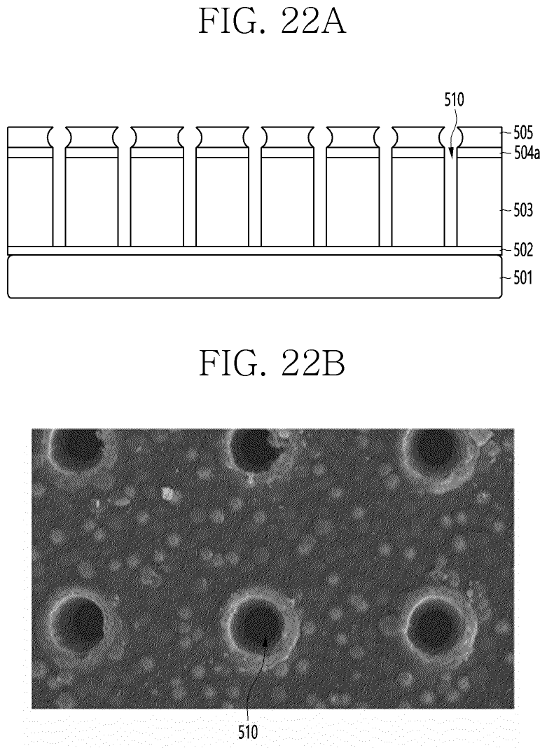

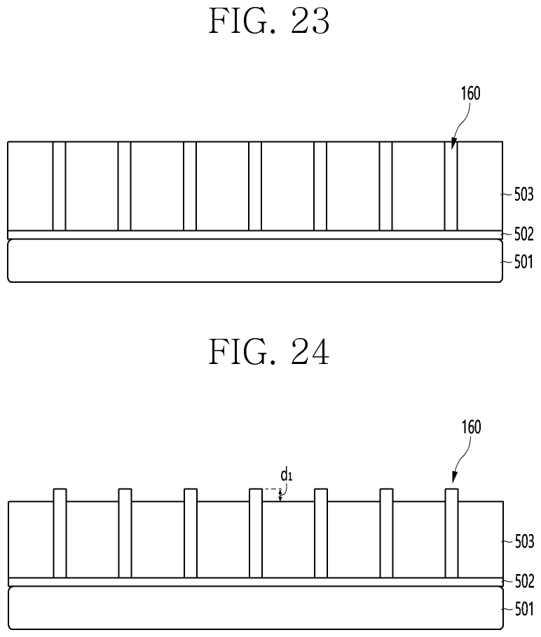

Hereinafter, a semiconductor light emitting device and a display device according to an embodiment will be described in detail with reference to FIGS. 12 to 30.

### [Semiconductor Light Emitting Device]

FIG. 12 is a cross-sectional view showing a semiconductor light emitting device according to a first embodiment.

Referring to FIG. 12, the semiconductor light emitting device 150 according to the first embodiment can comprise a first conductivity type semiconductor layer 151, an active layer 152, and a second conductivity type semiconductor layer 153. The semiconductor light emitting device 150 according to the first embodiment can comprise more components. For example, the first conductivity type semiconductor layer 151 can comprise at least one or more layers. For example, the active layer 152 can comprise at least one layer. For example, the second conductivity type semiconductor layer 153 can comprise at least one layer.

The first conductivity type semiconductor layer 151, the active layer 152, and the second conductivity type semiconductor layer 153 can form the light emitting structure 160. The light emitting structure 160 can have a cylindrical shape, but is not limited thereto.

The semiconductor light emitting device 150 according to the first embodiment can generate light of a specific color. The semiconductor light emitting device 150 according to the first embodiment can emit one of ultraviolet light, white light, blue light, green light, red light, and infrared light.

Meanwhile, the first conductivity type semiconductor layer 151, the active layer 152, and the second conductivity type semiconductor layer 153 can be grown sequentially using, for example, MOCVD equipment.

Conventionally, a first conductivity type semiconductor layer 151, an active layer 152, and a second conductivity type semiconductor layer 153 are sequentially grown on a wafer, and then a second conductivity type semiconductor layer is grown using a dry etching process. The layer 153, the active layer 152, and the first conductivity type semiconductor layer 151 can be sequentially etched to form a plurality of light emitting layers. Thereafter, a plurality of light emitting layers were separated from the wafer, and a plurality of semiconductor light emitting devices were manufactured.

During the dry etching process, the plasma density is different for each location on the wafer and the nano-scale patterns formed for the etching process are different from each other, so that the sizes (diameter and/or length) of a plurality of semiconductor light emitting devices manufactured on the wafer are different from each other. Therefore, when a plurality of semiconductor light emitting devices having different sizes are mounted on a display substrate (301 in FIG. 31), there is a problem that semiconductor light emitting devices that do not contact the electrodes on the display substrate 301 do not light up.

The embodiment may not use a dry etching process in the related art. That is, the embodiment does not require an etching process.

In general, free objects can be freely created depending on the shape of the mold. In the embodiment, the semiconductor light emitting device 150 can be manufactured in a previously prepared growth hole using the principle of a mold. That is, the previously prepared growth hole can have a shape corresponding to the semiconductor light emitting device 150 of the embodiment. In this instance, after sequentially growing the first conductivity type semiconductor layer 151, the active layer 152, and the second conductivity type semiconductor layer 153 using MOCVD equipment in a previously prepared growth hole, a member constituting the growth hole, For example, by removing the insulating film (503 in FIG. 16), the first conductivity type semiconductor layer 151, the active layer 152, and the second conductivity type semiconductor layer 153 grown in the growth hole have the light emitting structure 160 as it is. A semiconductor light emitting device 150 can be manufactured.

Conventionally, the first conductivity type semiconductor layer 151, the active layer 152, and the second conductivity type semiconductor layer 153 were sequentially grown on a wafer, and then the desired semiconductor light emitting device was manufactured through an etching process. In this instance, it was difficult to manufacture semiconductor light emitting devices of the same shape due to complex factors such as non-uniformity of plasma density and instability of temperature or power during the etching process. In particular, when miniaturizing a semiconductor light emitting device further, it has been very difficult to manufacture a semiconductor light emitting device with the same shape and small size as desired throughout the entire manufacturing process.

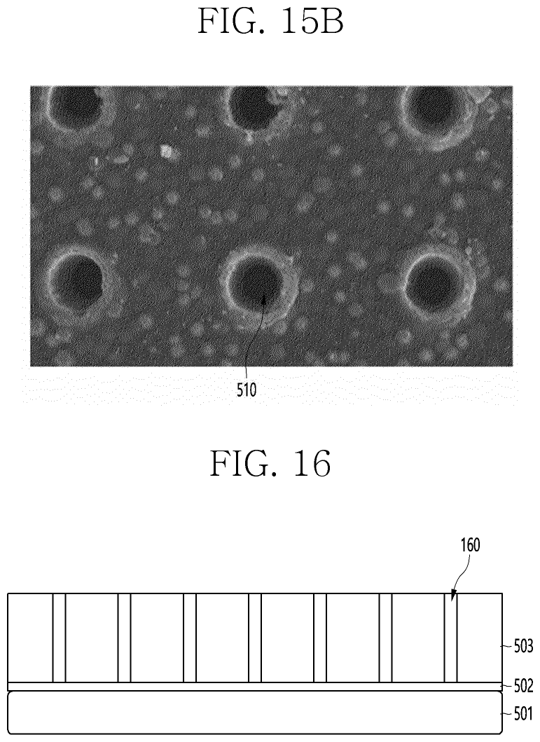

However, in the embodiment, by performing dry etching on the insulating film (503 in FIG. 15A) formed on the wafer, a growth hole with a minimum diameter and a desired depth in the vertical direction can be formed. Therefore, even if the diameter and length of the semiconductor light emitting device 150 to be manufactured are minimized, the growth hole that serves as a mold is formed to correspond to the diameter and length of the semiconductor light emitting device 150, so that that an ultra-small semiconductor light emitting device 150 can be manufactured. can be obtained, the semiconductor light emitting devices 150 of various shapes can be freely obtained, and each of the plurality of semiconductor light emitting devices 150 manufactured from the plurality of growth holes can have the same diameter and/or length.

As described above, since the embodiment does not use a dry etching process like the related art, problems caused by using a dry etching process in the related art can be solved.

That is, since the plurality of semiconductor light emitting devices 150 manufactured on the wafer have the same size, when the plurality of semiconductor light emitting devices 150 are mounted on the display substrate (301 in FIG. 31), lighting is possible in all pixels, preventing lighting defects.

Additionally, since the plurality of semiconductor light emitting devices 150 have the same size, each of the plurality of semiconductor light emitting devices 150 can have the same luminance. Therefore, when a plurality of semiconductor light emitting devices 150 are mounted on the display substrate 301, uniform luminance can be obtained in all pixels, and image quality can be improved.

The specific process of the semiconductor light emitting device 150 of the embodiment will be described later.

Referring again to FIG. 12, the active layer 152 can be disposed on the first conductivity type semiconductor layer 151, and the second conductivity type semiconductor layer can be disposed on the active layer 152.

The first conductivity type semiconductor layer 151, the active layer 152, and the second conductivity type semiconductor layer 153 can be made of a compound semiconductor material. For example, the compound semiconductor material can be a group 3-5 compound semiconductor material, a group 2-6 compound semiconductor material, etc. For example, the compound semiconductor material can comprise GaN, InGaN, AlN, AlInN, AlGaN, AlInGaN, InP, GaAs, GaP, GaInP, etc.

For example, the first conductivity type semiconductor layer 151 can comprise a first conductivity type dopant, and the second conductivity type semiconductor layer 153 can comprise a second conductivity type dopant. For example, the first conductivity type dopant can be an n-type dopant such as silicon Si, and the second conductivity type dopant can be a p-type dopant such as boron B.

The active layer 152 is a region that generates light, and can generate light with a specific wavelength band depending on the material properties of the compound semiconductor. That is, the wavelength band can be determined by the energy band gap of the compound semiconductor included in the active layer 152. Accordingly, light of various colors can be generated depending on the energy band gap of the compound semiconductor included in the active layer 152.

Since light is generated in the active layer 152, when the diameter (or size) of the active layer 152 of each of the plurality of semiconductor light emitting devices 150 manufactured on the wafer is different, the amount of light in the active layer 152 of each of the plurality of semiconductor light emitting devices 150 is different. That is, the amount of light from the semiconductor light emitting device 150 with a large diameter of the active layer 152 is greater than the amount of light from the semiconductor light emitting device 150 with a small diameter of the active layer 152. the amount of light can be directly related to luminance. In other words, the greater the amount of light, the greater the luminance.

In this way, when a display device is manufactured using a plurality of semiconductor light emitting devices 150 having different diameters manufactured on a wafer, the luminance of each pixel in the display device may be different from each other, causing poor image quality.

According to the embodiment, since each diameter (or size) of the plurality of semiconductor light emitting devices 150 manufactured on the wafer is the same, in a display device using these plural semiconductor light emitting devices 150, luminance can be uniform in each pixel, thereby improving image quality.

Additionally, according to an embodiment, the depth of the plurality of growth holes provided on the wafer can be the same, so that that the lengths of the plurality of semiconductor light emitting devices 150 manufactured from the plurality of growth holes can be the same. In this way, since both ends of the plurality of semiconductor light emitting devices 150 of the same length are stably in contact with the wiring electrode, lighting defects of the semiconductor light emitting devices 150 can be prevented.

In addition, according to an embodiment, since the inner surface of a plurality of growth holes provided on the wafer is a vertical surface with respect to the bottom surface and the vertical surface has a smooth surface with minimal roughness, the side surface of the semiconductor light emitting device 150 manufactured in this growth hole can have a vertical surface with respect to the lower surface, and the roughness of the vertical surface can be minimized.

In addition, according to the embodiment, by forming a plurality of growth holes provided on the wafer in various shapes, the shape of the semiconductor light emitting device 150 manufactured in the growth holes can be freely formed.

In the following embodiments, the description is limited to the fact that the growth hole is circular when viewed from above, but the growth hole in the embodiment can have a square shape, a polygon shape, a star shape, etc. Additionally, by forming the inner surface of the growth hole into a surface other than a vertical surface, such as a curved surface, a round surface, or a concave surface, the side surface of the semiconductor light emitting device 150 manufactured in the growth hole can also have various shapes.

FIGS. 13 to 17 show the manufacturing process of a semiconductor light emitting device according to the first embodiment.

In the following description, reference numerals for components not shown in FIGS. 13 to 17 can refer to FIG. 12.

As shown in FIG. 13, a wafer 501 can be prepared. The wafer 501 can be made of, for example, sapphire, but is not limited thereto.

A seed layer 502 can be formed on the wafer 501. The seed layer 502 can comprise a group II-VI compound or a group III-V compound, but is not limited thereto. The seed layer 502 can serve as a seed for growing a plurality of semiconductor layers constituting a semiconductor light emitting device.

If the wafer 501 contains a group II-VI compound or a group III-V compound and can serve as a seed, the seed layer 502 can be omitted.

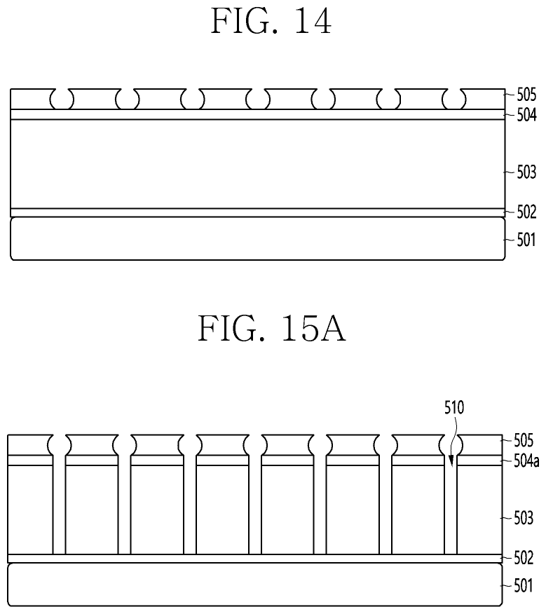

As shown in FIG. 14, an insulating film 503 and a mask film 504 can be sequentially formed on the seed layer 502. For example, the insulating film 503 can be made of an inorganic material such as SiOx, SiNx, etc. The mask film 504 can be made of a metal such as chromium Cr. Thereafter, a photosensitive pattern 505 can be formed by patterning the photosensitive film.

The insulating film 503 can be formed using, for example, thermal deposition equipment. When the insulating film 503 is formed using thermal evaporation equipment, the film quality of the insulating film 503 is hard and has excellent film quality, so that that the semiconductor light emitting device is later formed with excellent film quality, and the electrical and optical characteristics can be improved.

As shown in FIGS. 15A and 15B, a mask pattern 504a can be formed by patterning the mask film 504 using the photosensitive pattern 505 as a mask.

The photosensitive pattern 505 and the mask pattern 504a can have a transmissive area corresponding to the growth hole 510 and a non-transmissive area that is the remaining area.

After the photosensitive pattern 505 is removed, the insulating film 503 can be patterned using the mask pattern 504a as a mask to form a plurality of growth holes 510 on the wafer 501. The etching gas for forming the growth hole 510 can react with the insulating film 503 through the transmission area of the mask pattern 504a, and the insulating film 503 corresponding to the transmission area of the mask pattern 504a can be removed to form the growth hole 510. Accordingly, the mask pattern 504a can be formed considering the shape of the growth hole 510 or the diameter of the growth hole 510.

The bottom portion of the growth hole 510 can be the upper surface of the seed layer 502. That is, the upper surface of the seed layer 502 can be exposed by the growth hole 510.

The plurality of growth holes 510 can be formed in consideration of the number of semiconductor light emitting devices to be manufactured per wafer 501. Additionally, the plurality of growth holes 510 can be spaced apart from each other at an appropriate distance. For example, the distance between the plurality of growth holes 510 can be equal to or greater than the diameter of the growth holes 510, but is not limited thereto.

The growth hole 510 can be formed using photolithography or laser interference lithography.

Since unilateral etching is possible when photolithography is used, the growth hole 510 can be formed in a constant shape with the same diameter and great depth. That is, the growth hole 510 can be formed at a great depth by etching mainly in the depth direction using photolithography. For example, the inner surface of the growth hole 510 can have a straight surface perpendicular to the bottom portion, but is not limited thereto.

When laser interference lithography is used, the growth hole 510 can be formed with a smaller diameter than when photolithography is used.

For example, the diameter of the hole can be 1 μm or less. For example, the diameter of the hole can be 500 nm to 1 μm.

As shown in FIG. 16, the light emitting structure 160 can be grown within the growth hole 510 by using the seed layer 502 exposed within the growth hole 510 as a seed. As shown in FIG. 12, the light emitting structure 160 can comprise a first conductivity type semiconductor layer 151, an active layer 152, and a second conductivity type semiconductor layer 153. For example, the first conductivity type semiconductor layer 151 can be grown on the seed layer 502 using the seed layer 502 as a seed in the growth hole 510 using MOCVD equipment, an active layer 152 can be grown on the first conductivity type semiconductor layer 151, and a second conductivity type semiconductor layer 153 may be grown on the active layer 152. At this time, since the seed layer 502 is disposed only within the growth hole 510 and the seed layer 502 is not disposed on the upper surface of the insulating film 503, the light emitting structure 160 can be grown only within the growth hole 510 and does not grow on the upper surface of the insulating film 503.

As shown in FIG. 16, the upper surface of the light emitting portion 160 can be grown within the growth hole 510 to be coplanar with the upper surface of the insulating film 503, or can be grown lower or higher than the upper surface of the insulating film 503. For example, when the upper surface of the light emitting structure 160 is grown lower than the upper surface of the insulating film 503, the upper surface of the light emitting structure 160 can have a downward concave shape. For example, when the upper surface of the light emitting structure 160 is grown higher than the upper surface of the insulating film 503, the upper surface of the light emitting structure 160 can have an upward convex shape. Here, downward can be a direction toward the wafer 501, and upward can be a direction away from the wafer 501.

As shown in FIG. 17, by removing the insulating film 503, a plurality of light emitting structures 160 can be positioned on the wafer 501. For example, the insulating film 503 can be removed using a wet etching process, but is not limited thereto.

Although not shown, a separate insulating film 503 can be formed along the perimeter of the light emitting structure 160. Thereafter, after the insulating film 503 formed on the upper side of the light emitting structure 160 can be removed, an upper electrode can be formed on the upper side of the light emitting structure 160. Thereafter, after the plurality of light emitting structures 160 are attached on the upper side to a separate substrate, the wafer 501 can be separated. Thereafter, a lower electrode can be formed on the lower side of the light emitting structure 160 from which the wafer 501 is separated.

As another example, after first separating the plurality of light emitting structures 160 from the wafer 501, the insulating film 503, the upper electrode, and the lower electrode can be formed.

As shown in FIG. 17, a plurality of light emitting structures 160 manufactured by growing in a plurality of growth holes 510 having the same diameter and the same depth can also have the same diameter and the same depth. At this time, the light emitting structure 160 is a semiconductor light emitting device, and the side surface of the light emitting structure 160 can have a straight surface perpendicular to the lower surface of the light emitting structure 160, but is not limited thereto.

The light emitting structure 160 can have a shape corresponding to the shape of the growth hole 510. The light emitting structure 160 can have a circular shape, square shape, polygon shape, star shape, etc.

According to the embodiment, a plurality of light emitting structures 160 having the same diameter and the same depth can be easily manufactured in large quantities. When implementing a display using the plurality of light emitting structures 160 manufactured in this way, that is, semiconductor light emitting devices, uniform luminance can be secured and lighting defects can be minimized.

According to the embodiment, semiconductor light emitting devices of various shapes can be freely manufactured by varying the shape of the growth hole 510.

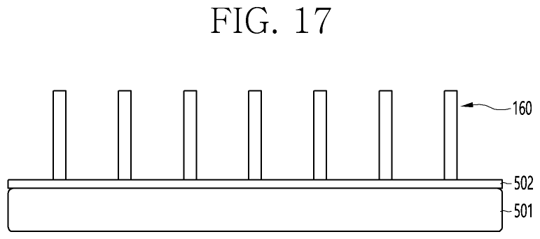

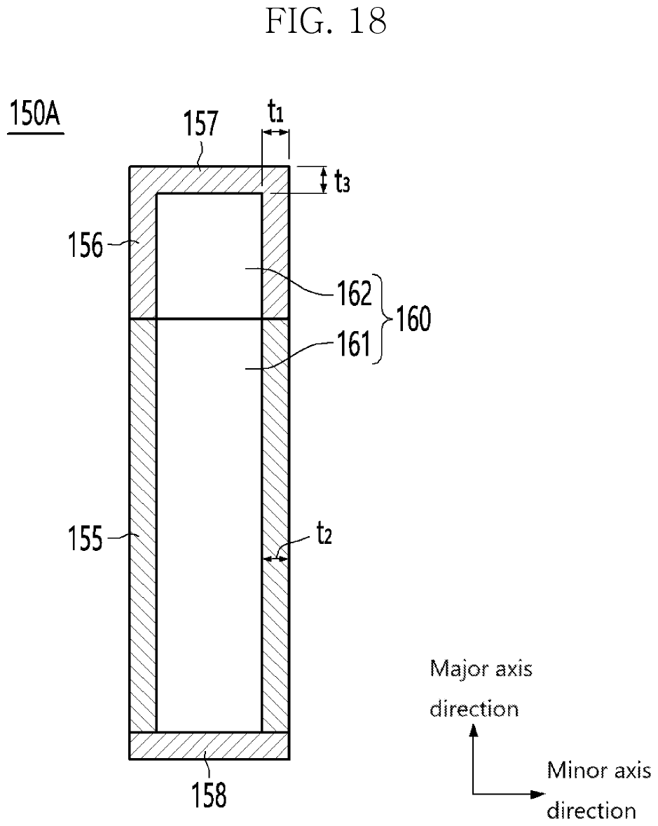

Hereinafter, the second embodiment will be described with reference to FIG. 18.

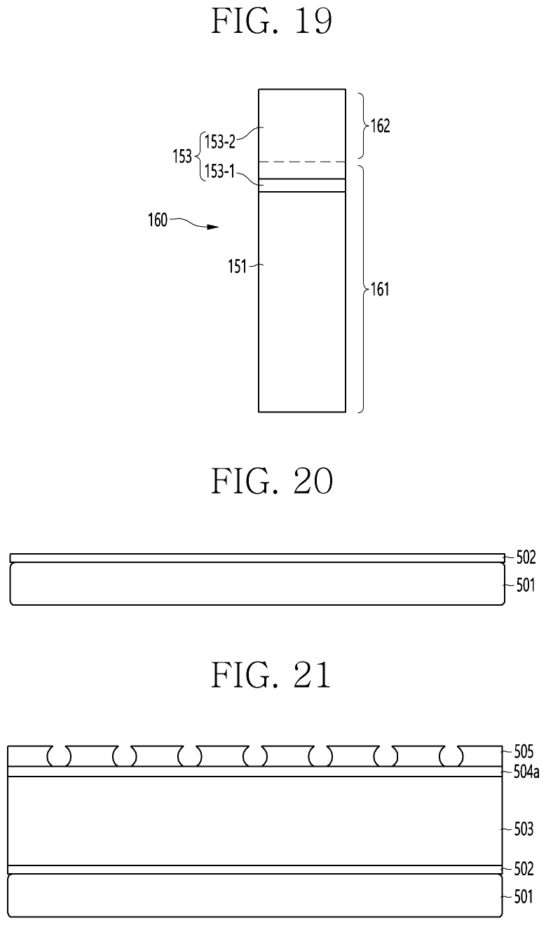

FIG. 18 is a cross-sectional view showing a semiconductor light emitting device according to a second embodiment. FIG. 19 is a cross-sectional view showing the light emitting structure of FIG. 18 in detail.

The second embodiment is the same as the first embodiment except for the insulating layer 155 and the electrodes 156 to 158. In the second embodiment, the same reference numerals are given to the same components having the same shape, structure, and/or function as those of the first embodiment, and detailed descriptions are omitted.

Referring to FIG. 18, the semiconductor light emitting device 150A according to the second embodiment can comprise a light emitting structure 160, an insulating layer 155, and electrodes 156 to 158.

The light emitting structure 160 can have a first region 161 and a second region 162. The first region 161 and the second region 162 can be located along the major axis direction of the light emitting structure 160. The major axis direction can be the longitudinal direction of the light emitting structure 160. The second region 162 can be disposed on the first region 161. Alternatively, the first region 161 can be disposed below the second region 162.

As will be explained later, both the first region 161 and the second region 162 of the light emitting structure 160 are manufactured in the growth hole formed on the wafer 501, so that no etching process is involved. Since the light emitting structure 160 is manufactured corresponding to the inner surface of the growth hole, the diameter of the first region 161 and the diameter of the second region 162 can be the same. In addition, the side surface of the first region 161 and the side surface of the second region 162 can coincide along the major axis or length direction of the light emitting structure 160.

Accordingly, the semiconductor light emitting device 150A, in which the insulating layer 155 and the electrodes 156 to 158 are disposed on the light emitting structure 160 manufactured in a plurality of growth holes on the wafer 501, can have the same diameter and the same length on both the lower and upper sides. When implementing a display using a plurality of semiconductor light emitting devices 150A, both ends of each of the plurality of semiconductor light emitting elements 150A can be electrically in contact with the assembling wirings, thereby preventing lighting defects and improving image quality by ensuring uniform luminance between each pixel.

As shown in FIG. 19, the light emitting structure 160 can comprise a first conductivity type semiconductor layer 151, an active layer 152, and a second conductivity type semiconductor layer 153. In this instance, the first region 161 can comprise a first conductivity type semiconductor layer 151 and an active layer 152, and the second region 162 can comprise a second conductivity type semiconductor layer 153. For example, the first region 161 can comprise not only the first conductivity type semiconductor layer 151 and the active layer 152, but also a partial region of the second conductivity type semiconductor layer 153 (a second-first conductivity type semiconductor layer 153_1). For example, the second region 162 can comprise another region of the second conductivity type semiconductor layer 153 (a second-second conductivity type semiconductor layer 153-2). The second-first conductivity type semiconductor layer 153_1 and the second-second conductivity type semiconductor layer 153-2 can be separated for convenience, and can be formed integrally with substantially the same material through the same process.

The insulating layer 155 can surround the side surface of the first region 161. The insulating layer 155 can be a protective layer that protects the light emitting structure 160.

For example, the insulating layer 155 can be disposed along the side perimeter of the side surface of the first region 161. For example, the insulating layer 155 can surround each side surface of the first conductivity type semiconductor layer 151, the active layer 152, and the second-first conductivity type semiconductor layer 153_1.

For example, the insulating layer 155 can be made of an inorganic material such as SiOx, SiNx, etc.

For example, the insulating layer 155 can prevent leakage current flowing along the side surface of the light emitting structure 160 when light is emitted. For example, the insulating layer 155 can prevent an electrical short circuit between the first conductivity type semiconductor layer 151 and the second conductivity type semiconductor layer 153 due to foreign substances, etc. For example, when the semiconductor light emitting devices 150A are assembled on the display substrate (301 in FIG. 31) by self-assembly method, the insulating layer 155 allows the lower side of the semiconductor light emitting device 150A, that is, the first conductivity type semiconductor layer 151, to be in contact with the display substrate 301 so that the semiconductor light emitting device 150A can be assembled correctly.

The electrodes can comprise a first electrode 156, a second electrode 157, and a third electrode 158. The first electrode 156 and the second electrode 157 can constitute an upper electrode, and the third electrode 158 can be a lower electrode.

The electrodes 156 to 158 can be made of a metal with excellent conductivity. The electrodes 156 to 158 can comprise at least one of copper (Cu), aluminum (Al), titanium (Ti), nickel (Ni), platinum (Pt), gold (Au), and silver (Ag).

The first electrode 156 can surround the side surface of the second region 162.

As will be explained later, the insulating layer 155 can be formed using the first electrode 156 as a mask. Accordingly, the thickness t2 of the insulating layer 155 can be the same as the thickness t1 of the first electrode 156. Since the insulating layer 155 is formed using the first electrode 156 as a mask, there is no need to form a separate mask to form the insulating layer 155, so that the process can be simple and material costs can be reduced.

Meanwhile, the first electrode 156 may not be in contact with the active layer 152. When the first electrode 156 is in contact with the active layer 152, the current does not flow to the active layer 152 through the second conductivity type semiconductor layer 153, but flows directly to the active layer 152 through the first electrode 156. Therefore, holes are not generated in the second conductivity type semiconductor layer 153 and the semiconductor light emitting device 150A does not emit light.

Accordingly, the first electrode 156 can be disposed around the upper side of the second conductivity type semiconductor layer 153 and can be spaced apart from the active layer 152, so that it may not be in contact with the active layer 152.

For example, the first electrode 156 can overlap the insulating layer 155 along the major axis direction. For example, the first electrode 156 and the insulating layer 155 can be in contact along the perimeter of the light emitting structure 160. As will be explained later, since the insulating layer 155 is formed using the first electrode 156 as a mask, the insulating layer 155 can be formed in the same shape as the first electrode 156. Therefore, the thickness t2 of the insulating layer 155 can be equal to the thickness t1 of the first electrode 156, the upper surface of the insulating layer 155 can be in contact with the lower surface of the first electrode 156, and the first electrode 156 and the insulating layer 155 can overlap along the major axis direction.

Meanwhile, the second electrode 157 can be disposed on the upper surface of the second region 162 of the light emitting structure 160. The second electrode 157 can be omitted.

The first electrode 156 and the second electrode 157 can be formed integrally, but is not limited thereto. For example, the second electrode 157 can be formed extending from the first electrode 156. That is, the first electrode 156 can surround the side surface of the second region 162 of the light emitting structure 160 and the second electrode 157 can extend from the first electrode 156 and be disposed on the upper surface of the second region 162.

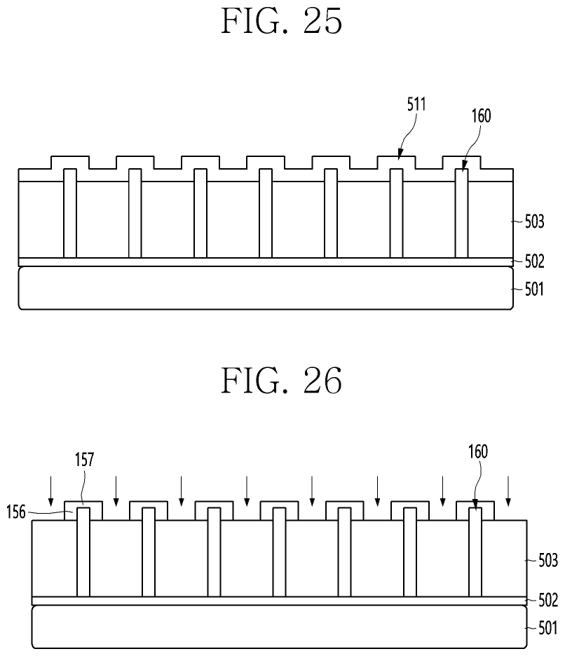

The thickness t1 of the first electrode 156 and the thickness t3 of the second electrode 157 can be different. For example, the thickness t1 of the first electrode 156 can be greater than the thickness t3 of the second electrode 157. As will be explained later, after the metal film (511 in FIG. 25) is formed on the side surface and upper surface of the light emitting structure 160, if an etching process is performed without a mask, the metal film 511 on the upper surface of the light emitting structure 160 is removed faster than the metal film 511 on the side surface of the light emitting structure 160. Therefore, the thickness t1 of the metal film 511 on the side surface of the light emitting structure 160, that is, the first electrode 156, is greater than the thickness t3 of the metal film 511 on the upper surface of the light emitting structure 160, that is, the second electrode 157. The metal film 511 on the upper surface of the light emitting structure 160, i.e., the second electrode 157, can be removed, and only the metal film 511 on the side surface of the light emitting structure 160, i.e., the first electrode 156, can remain.

Meanwhile, the third electrode 158 can be disposed on the lower surface of the first region 161 of the light emitting structure 160. For example, the third electrode 158 can comprise at least one layer.

The third electrode 158 can be disposed on the lower surface of the insulating layer 155. That is, the insulating layer 155 and the third electrode 158 can be in contact along the perimeter of the light emitting structure 160. For example, the insulating layer 155 and the third electrode 158 can overlap along the major axis direction.

Although not shown in the drawing, the third electrode 158 may not be disposed on the lower surface of the insulating layer 155 but only on the lower surface of the first region 161 of the light emitting structure 160.

FIGS. 20 to 28 show the manufacturing process of a semiconductor light emitting device according to the second embodiment.

In the following description, reference numerals for components not shown in FIGS. 20 to 28 can refer to FIGS. 18 and 19.

Since FIGS. 20 to 23 are the same as FIGS. 13 to 16, detailed description is omitted.

As shown in FIG. 24, a part of the insulating film 503 can be removed using an etching process. By removing a part of the insulating film 503, a part of the light emitting structure 160, for example, a part of the second conductivity type semiconductor layer 153, that is, the second-second conductivity type semiconductor layer 153-2 can be exposed. The depth dl of the removed insulating film 503 can be equal to the thickness of the second-second conductivity type semiconductor layer 153-2.

For example, since the active layer 152 of the light emitting structure 160 is buried in the insulating film 503, it may not be exposed. In addition, since another part of the second conductivity type semiconductor layer 153, that is, the second-first conductivity type semiconductor layer 153_1, is also buried in the insulating film 503, it may not be exposed.

As shown in FIG. 25, a metal film 511 can be formed on the insulating film 503 and the light emitting structure 160. For example, the metal film 511 can be formed using a sputtering deposition process, but is not limited thereto.

The thickness of the metal film 511 formed on the insulating film 503 and the light emitting structure 160 may be different, but is not limited thereto. For example, the thickness of the metal film 511 on the insulating film 503 can be the smallest, and the metal film 511 formed on the side and upper surfaces of the second-second conductivity type semiconductor layer 153-2 of the light emitting structure 160 can be formed relatively thick.

As shown in FIG. 26, a dry etching process can be performed on the metal film 511. Since the etch rate is greater in the vertical direction than in the horizontal direction due to the dry etching process, even if all of the metal film 511 on the insulating film 503 having the smallest thickness can be removed, only a part of the metal film 511 formed on the side and upper surfaces of the second-second conductivity type semiconductor layer 153-2 may be removed. In particular, the metal film 511 on the upper surface of the second-second conductivity type semiconductor layer 153-2 can be removed faster than the metal film 511 on the side surface of the second-second conductivity type semiconductor layer 153-2.

Accordingly, all of the metal film 511 on the insulating film 503 can be removed, and the thickness of the metal film 511 on the side surface of the second-second conductivity type semiconductor layer 153-2 can be greater than the thickness of the metal film 511 on the upper surface of the second-second conductivity type semiconductor layer 153-2. The metal film 511 on the side surface of the second-second conductivity type semiconductor layer 153-2 can be the first electrode 156, and the metal film 511 on the upper surface of the second-second conductivity type semiconductor layer 153-2 can be the second electrode 157.

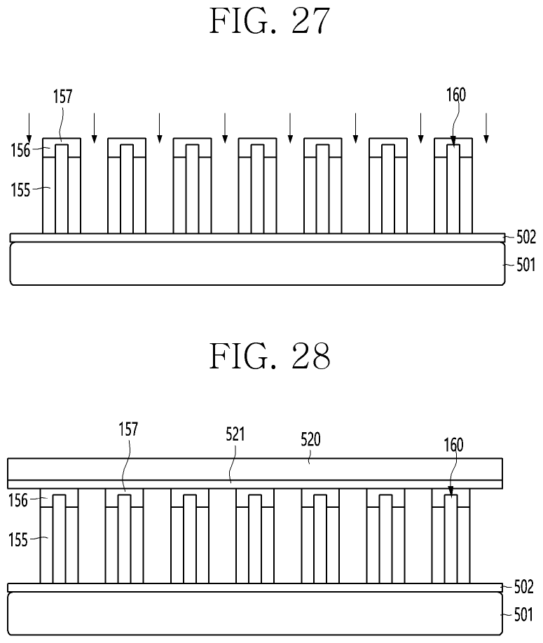

As shown in FIG. 27, the insulating film 503 can be removed by performing a dry etching process using the upper electrodes 156 and 157 comprising the first electrode 156 and the second electrode 157 as a mask. Since etching is performed along the vertical direction by the dry etching process, the insulating film 503 exposed between the upper electrodes 156 and 157 can be removed vertically. At this time, the insulating film 503 vertically overlapping the upper electrodes 156 and 157, especially the first electrode 156, can remain without being removed by a dry etching process to form the insulating layer 155.

Since the insulating layer 155 is formed through a dry etching process, the outer surface of the insulating layer 155 can have irregularities. Accordingly, the light extraction efficiency of the light emitting structure 160 can be increased by the unevenness provided on the outer surface of the insulating layer 155, so that light efficiency or light output can be improved, which can lead to increased luminance when implementing display.

The dry etching process can be continuously performed until the upper surface of the seed layer 502 is exposed.

Accordingly, the insulating layer 155 can be disposed around the light emitting structure 160, and an upper electrode comprising the first and second electrodes 156 and 157 can be disposed on the upper side of the light emitting structure 160.

As shown in FIG. 28, the substrate 520 can be positioned on the wafer 501 and attached to the upper electrodes 156 and 157. That is, the substrate 520 can be attached to the upper electrodes 156 and 157 using an adhesive member 521 such as a tape. The substrate 520 can be glass, but is not limited thereto.

Afterwards, the plurality of light emitting structures 160 on the wafer 501 can be transferred onto the substrate 520 using a laser lift-off process. That is, by focusing the laser on the seed layer 502, the plurality of light emitting structures 160 can be separated from the wafer 501 based on the seed layer 502.

As another example, a plurality of light emitting structures 160 on the wafer 501 can be transferred onto the substrate 520 using a chemical lift-off process. For example, when the wafer 501 is immersed in a water bath containing an etchant and then ultrasonic waves are applied, the seed layer 502 can be removed by the etchant, and vibration is applied to the wafer 501 by the ultrasonic waves, so that the plurality of light emitting structures 160 can be separated from the wafer 501 based on the seed layer 502.

When using a chemical lift-off process, the lower surface of the light emitting structure 160 can have a smooth, flat surface.

Although not shown, the lower electrode 158 can be formed on the lower surface of the light emitting structure 160 in a later process, so that that a semiconductor light emitting device can be manufactured. Thereafter, the semiconductor light emitting devices can be separated from the substrate 520.

According to an embodiment, a plurality of light emitting structures 160 with the same diameter and/or length can be obtained by growing a plurality of semiconductor layers in the growth hole 510 previously formed on the wafer 501.

According to the embodiment, the electrodes 156 to 158 and the insulating layer 155 can be formed in the process of manufacturing the plurality of light emitting structures 160, so that there is no need to form a separate electrode or insulating layer 155, thereby be simple process and reducing material costs.

According to the embodiment, the insulating layer 155 can be formed using the upper electrodes 156 and 157, especially the first electrode 156, as a mask, so that there is no need to form a separate mask, thereby be simple process and reducing material costs.

As described above, since the diameter and/or length of the plurality of semiconductor light emitting devices manufactured on the wafer 501 are the same, lighting defects can be prevented and image quality can be improved by eliminating luminance deviation when implementing display using these semiconductor light emitting devices.

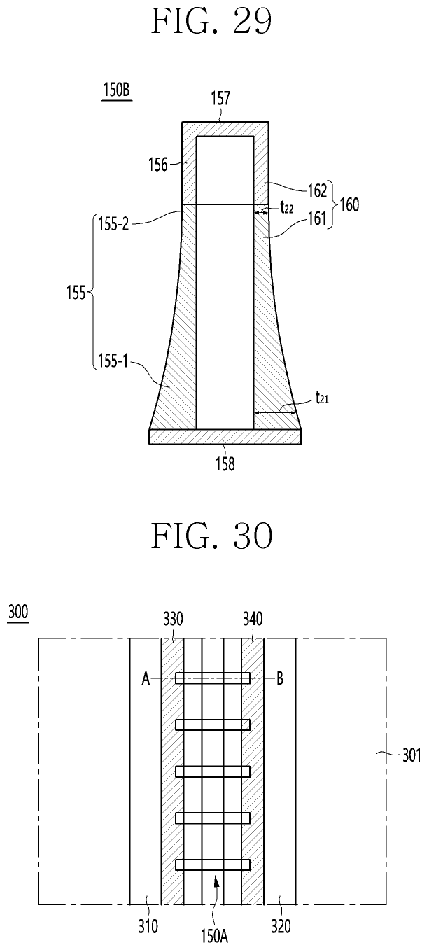

Hereinafter, the third embodiment will be described with reference to FIG. 29.

FIG. 29 is a cross-sectional view showing a semiconductor light emitting device according to a third embodiment.

The third embodiment can be the same as the second embodiment except for the shape of the insulating layer 155. In the third embodiment, the same reference numerals are given to the same components having the same shape, structure, and/or function as those of the second embodiment, and detailed descriptions are omitted.

Referring to FIG. 29, the semiconductor light emitting device 150B according to the third embodiment can comprise a light emitting structure 160, an insulating layer 155, and electrodes 156 to 158.

The light emitting structure 160 has been described in detail in the first and second embodiments, and detailed description will be omitted.

The insulating layer 155 can comprise a first insulating layer 155-1 and a second insulating layer 155-2.

The first insulating layer 155-1 can be disposed along a part of the first region 161, and the second insulating layer 155-2 can be disposed along another part of the first region 161. For example, the first insulating layer 155-1 can surround the side surface of the first conductivity type semiconductor layer 151, and the second insulating layer 155-2 can surround the side surface of the active layer 152. The second insulating layer 155-2 can surround the side surfaces of the active layer 152 as well as the second conductivity type semiconductor layer 153, that is, the second-first conductivity type semiconductor layer 153_1.

For example, the thickness t21 of the first insulating layer 155-1 can be greater than the thickness t22 of the second insulating layer 155-2. For example, the outer surface of the first insulating layer 155-1 can have a concave round shape. For example, the thickness t21 of the first insulating layer 155-1 can be thickest in the lower side of the first region 161. That is, the first insulating layer 155-1 can have a thickness equal to the thickness t22 of the second insulating layer 155-2 in the first insulating area in contact with the second insulating layer 155-2. The first insulating layer 155-1 can extend from the first insulating region and the thickness t21 increases, so that the outer surface of the first insulating layer 155-1 can have a concave round shape. The concave round shape of the first insulating layer 155-1 can be explained in the manufacturing process of the semiconductor light emitting device 150B. In FIG. 27, when the insulating film 503 can be removed by a dry etching process, the etch rate in the vertical direction can be greater than the etch rate in the horizontal direction, so that the insulating film 503 can be mainly removed along the vertical direction, but can be also slightly removed in the horizontal direction. Accordingly, while the lower side of the insulating film 503 is etched, the upper side of the insulating film 503 can be continuously removed along the horizontal direction, so that a first insulating layer 155-1 having a concave round shape can be formed, as shown in FIG. 29.

Meanwhile, the lower electrode 158 can be disposed on the lower surface of the light emitting structure 160 and the lower surface of the insulating layer 155. Since the lower electrode 158 has the thickest thickness (t21) in the lower side of the insulating layer 155, that is, the first insulating layer 155-1, the lower electrode 158 can have thicker diameter than the upper electrodes 156 and 157.

Since the lower electrode 158 has a relatively large diameter, the contact area between the wiring electrode and the lower electrode 158 is large during the wiring electrode pattern process after mounting on the display substrate (301 in FIG. 31) to prevent contact defects.

### [Display Device]

FIG. 30 is a plan view showing a display device according to an embodiment. FIG. 31 is a cross-sectional view showing a display device according to an embodiment.

In the following description, reference numerals for components not shown in FIGS. 30 and 31 can refer to FIGS. 12 to 29.

Referring to FIGS. 30 and 31, the display device 300 according to the embodiment can comprise a substrate 301, a dielectric layer 302, assembling wirings 310 and 320, and wiring electrodes 330 and 340. At least one layer can be disposed on the wiring electrodes 330 and 340.

Since the substrate 301 is the same as the substrate 200 in FIG. 9 and the assembling wirings 310 and 320 are the same as the wiring electrodes 201 and 202 in FIG. 9, detailed descriptions are omitted.

A plurality of semiconductor light emitting devices 150A can be aligned between the assembling wirings 310 and 320 by a dielectrophoretic force caused by an electric field generated between the assembling wirings 310 and 320.

FIGS. 30 and 31 show the semiconductor light emitting device 150A according to the second embodiment, the display device 300 using the semiconductor light emitting device 150 and 150B according to the first and third embodiments can also be manufactured.

The dielectric layer 302 can be disposed on the assembling wiring 310 and 320 to help generate an electric field and prevent short circuits between the assembling wiring 310 and 320.

The wiring electrodes 330 and 340 can be disposed on the assembling wirings 310 and 320 and can be electrically connected to each of the plurality of semiconductor light emitting devices 150A.

As an example, when the plurality of semiconductor light emitting devices 150A generate monochromatic light, for example, blue light, the first wiring electrode 330 can be commonly connected to one side of the plurality of semiconductor light emitting devices 150A, the second wiring electrode 340 can be commonly connected to the other side of the plurality of semiconductor light emitting devices. A part of the first wiring electrode 330 can be disposed on one side of each of the plurality of semiconductor light emitting devices 150A, for example, the upper electrodes 156 and 157, and a part of the second wiring electrode 340 can be disposed on the other side of each of the plurality of semiconductor light emitting devices 150A, for example, the lower electrode 158. For example, the first wiring electrode 330 can be an anode electrode, and the second wiring electrode 340 can be a cathode electrode, but is not limited thereto.

The first and second wiring electrodes 330 and 340 can be commonly connected to a power source for emitting light from the plurality of semiconductor light emitting devices 150A, while firmly fixing the plurality of semiconductor light emitting devices 150A.

As another example, the plurality of semiconductor light emitting devices 150A can comprise a first semiconductor light emitting device that generates red light, a second semiconductor light emitting device that generates green light, and a third semiconductor light emitting device that generates blue light.

In this instance, the first wiring electrode 330 can comprise a first-first wiring electrode, a first-second wiring electrode, and a first-third wiring electrode. The first-first wiring electrode can be electrically connected to the upper electrodes 156 and 157 of the first semiconductor light emitting device, the first-second wiring electrode can be electrically connected to the upper electrodes 156 and 157 of the second semiconductor light emitting device, and the first to third wiring electrodes can be electrically connected to the upper electrodes 156 and 157 of the third semiconductor light emitting device. For example, the second wiring electrode 340 can be commonly connected to the lower electrode 158 of each of the first to third semiconductor pore-emitting devices.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

### INDUSTRIAL APPLICABILITY

The embodiment can be adopted in the field of displays that display images or information.

The embodiment can be adopted in the field of displays that display images or information using semiconductor light emitting devices.

The embodiment can be adopted in the field of displays that display images or information using micro-level or nano-level semiconductor light emitting devices.

1. A semiconductor light emitting device, comprising:
a light emitting structure having a first region and a second region along the major axis direction;
an insulating layer surrounding a side surface of the first region; and
a first electrode surrounding a side surface of the second region,
wherein the thickness of the insulating layer is the same as the thickness of the first electrode,
wherein the light emitting structure comprises:
a first conductivity type semiconductor layer;
an active layer on the first conductivity type semiconductor layer; and
a second conductivity type semiconductor layer on the active layer, wherein the insulating layer comprises:
a first insulating layer surrounding a side surface of the first conductivity type semiconductor layer; and
a second insulating layer surrounding a side surface of the active layer.

2. (canceled)

3. The semiconductor light emitting device of claim 1, wherein
the first region comprises the first conductivity type semiconductor layer and the active layer, and
the second region comprises the second conductivity type semiconductor layer.

4. The semiconductor light emitting device of claim 3, wherein
the first region comprises a part of the second conductivity type semiconductor layer.

5. The semiconductor light emitting device of claim 3, wherein
the diameter of the first region is the same as the diameter of the second region.

6. The semiconductor light emitting device of claim 3, wherein
the side surface of the first region and the side surface of the second region coincide along the major axis direction.

7. (canceled)

8. The semiconductor light emitting device of claim 1, wherein
the thickness of the first insulating layer is greater than the thickness of the second insulating layer.

9. The semiconductor light emitting device of claim 1, wherein
the outer surface of the first insulating layer has a concave round shape.

10. The semiconductor light emitting device of claim 1, wherein
the thickness of the first insulating layer is the thickest in a lower side of the first region.

11. The semiconductor light emitting device of claim 1, wherein
the first electrode is not in contact with the active layer.

12. The semiconductor light emitting device of claim 1, wherein
the first electrode and the insulating layer overlap each other along the major axis direction.

13. The semiconductor light emitting device of claim 1, wherein
the first electrode and the insulating layer are in contact along the perimeter of the light emitting structure.

14. The semiconductor light emitting device of claim 1, comprising:
a second electrode disposed on an upper surface of the second region.

15. The semiconductor light emitting device of claim 14, wherein
the first electrode and the second electrode are formed integrally.

16. The semiconductor light emitting device of claim 14, wherein
the thickness of the first electrode and the thickness of the second electrode are different.

17. The semiconductor light emitting device of claim 16, wherein
the thickness of the first electrode is greater than the thickness of the second electrode.

18. The semiconductor light emitting device of claim 1, comprising:
a third electrode on a lower surface of the first region.

19. The semiconductor light emitting device of claim 1, wherein
the light emitting part has a cylindrical shape.

20. A display device, comprising:
a substrate;
first and second assembling wirings on the substrate;
a plurality of semiconductor light emitting devices disposed on the first and second assembling wirings to generate different color lights;
a first wiring electrode on one side of each of the plurality of semiconductor light emitting devices; and
a second wiring electrode on the other side of each of the plurality of semiconductor light emitting devices,
wherein the plurality of semiconductor light emitting devices each comprises:
a light emitting structure having a first region and a second region along the major axis direction;
an insulating layer surrounding a side surface of the first region; and
a first electrode surrounding a side surface of the second region,
wherein the thickness of the insulating layer is the same as the thickness of the first electrode,
wherein the light emitting structure comprises:
a first conductivity type semiconductor layer;
an active layer on the first conductivity type semiconductor layer; and
a second conductivity type semiconductor layer on the active layer,
wherein the insulating layer comprises:
a first insulating layer surrounding a side surface of the first conductivity type semiconductor layer; and
a second insulating layer surrounding a side surface of the active layer.

21. The display device of claim 20, wherein
the thickness of the first insulating layer is greater than the thickness of the second insulating layer.

22. The display device of claim 20, wherein
the thickness of the first insulating layer is the thickest in a lower side of the first region.
